(19) United States
(12) Patent Application Publication
(10) Pub. No.: US 2022/0128906 A1
(43) Pub. Date: Apr. 28, 2022

(54) PHOTORESIST PATTERN TRIMMING COMPOSITIONS AND METHODS OF TRIMMING PHOTORESIST PATTERNS

(71) Applicant: Rohm and Haas Electronic Materials LLC, Marlborough, MA (US)

(72) Inventors: Irvinder Kaur, Northborough, MA (US); Cong Liu, Shrewsbury, MA (US); Kevin Rowell, Salem, MA (US)

(21) Appl. No.: 17/081,258

(22) Filed: Oct. 27, 2020

(51) Int. Cl. G03F 7/039; H01L 21/027; H01L 21/311

(52) U.S. Cl. CPC G03F 7/0397; H01L 21/31138; H01L 21/0274

(57) ABSTRACT

Photoresist pattern trimming compositions comprise: a polymer comprising as polymerized units a monomer comprising an acid-decomposable group, the decomposition of which group forms a carboxylic acid group on the polymer; a non-polymeric acid or a non-polymeric thermal acid generator; and an organic-based solvent system comprising one or more organic solvents. Methods of trimming photoresist patterns involve applying such pattern trimming compositions to a photoresist pattern that is formed from a photoresist composition comprising a photoacid generator and a polymer comprising acid-decomposable groups. The photoresist pattern trimming compositions and pattern formation methods find particular use in the formation of fine lithographic patterns in the semiconductor manufacturing industry.

### BACKGROUND OF THE INVENTION

### 1. Field of the Invention

The invention relates generally to the manufacture of electronic devices. More specifically, this invention relates to photoresist pattern trimming compositions and to methods of trimming photoresist patterns using such compositions. The compositions and methods find particular use in the formation of fine lithographic patterns useful in the manufacture of semiconductor devices.

### 2. Description of the Related Art

In the semiconductor manufacturing industry, photoresist layers are used for transferring an image to one or more underlying layers, such as metal, semiconductor or dielectric layers, disposed on a semiconductor substrate, as well as to the substrate itself. To increase the integration density of semiconductor devices and allow for the formation of structures having dimensions in the nanometer range, photoresist compositions and photolithography processing tools having high-resolution capabilities have been and continue to be developed.

Positive-tone chemically amplified photoresist compositions are conventionally used for high-resolution processing. Such compositions typically employ a photoacid generator (PAG) and a polymer having acid-labile groups. Pattern-wise exposure of a layer formed from such photoresist composition to activating radiation causes the acid generator to form an acid which, during post-exposure baking, causes cleavage of the acid-labile groups in exposed regions of the photoresist layer. This creates a difference in solubility characteristics between exposed and unexposed regions of the layer in a developer solution. In a positive tone development (PTD) process, exposed regions of the photoresist layer become soluble in the developer and are removed from the substrate surface, whereas unexposed regions, which are insoluble in the developer, remain after development to form a positive image. The resulting relief image permits selective processing of the substrate.

Lithographic scaling has conventionally been achieved by increasing the numerical aperture of optical exposure tools and by use of shorter exposure wavelengths. To form finer photoresist patterns than attainable by direct imaging alone, photoresist pattern trimming processes have been proposed, for example, in U.S. Patent Application Publication Nos. US2013/0171574A1, US2013/0171825A1, US2014/0186772A1, and US2016/0187783A1. Photoresist pattern trimming processes typically involve contacting a photoresist pattern that includes a polymer having acid-labile groups with a trimming composition containing a polymer and an acid or thermal acid generator. The acid or generated acid in the trimming composition causes deprotection of the resist polymer in a surface region of the resist pattern, which region is then removed by contact with a rinsing agent such as an aqueous base developer (e.g., TMAH) solution. This allows for trimming of the photoresist pattern, resulting, for example, in the creation of finer resist line or pillar patterns than when using direct imaging alone.

KrF (248 nm) and extreme ultraviolet (EUV) photoresist materials typically include polymers that are vinyl aromatic-based, for example, hydroxystyrene-based. These materials generally include beneficial etch resistance, etch selectivity, and sensitivity properties, as well as low cost. These benefits compare favorably with conventional ArF (193 nm) photoresist materials which typically contain (meth)acrylate polymers and are substantially free of aromatic groups due to their high absorption at the ArF exposure wavelength. Pattern trimming compositions designed for ArF photoresist patterns can be incompatible with KrF and EUV photoresist patterns given the significantly different polymer chemistries of ArF versus KrF and EUV photoresist compositions. Such incompatibility can be exhibited, for example, in severe pattern damage caused by washing away of the resist pattern due to dissolution in the trimming composition's casting solvent. To address this problem, a non-polar-based hydrophobic casting solvent can be used in the trimming compositions. This, however, places additional constraints on the trimming composition polymer, which should be soluble both in the casting solvent and the rinsing agent. Insolubility of the trimming composition polymer in the casting solvent can result in coating nonuniformities and patterning defects, and insolubility in the rinsing agent can result in patterning defects and ineffective trimming. These insolubility issues can adversely impact performance and/or yield of resulting electronic devices.

There is a need in the art for improved photoresist pattern trimming compositions and pattern formation methods that address one or more problems associated with the state of the art.

### SUMMARY OF THE INVENTION

In accordance with a first aspect of the invention, photoresist pattern trimming compositions are provided. The compositions comprise: a polymer comprising as polymerized units a monomer comprising an acid-decomposable group, the decomposition of which group forms a carboxylic acid group on the polymer; a non-polymeric acid or a non-polymeric thermal acid generator; and an organic-based solvent system comprising one or more organic solvents.

Also provided are methods of trimming a photoresist pattern. The methods comprise: (a) providing a semiconductor substrate; (b) forming a photoresist pattern over the semiconductor substrate, wherein the photoresist pattern is formed from a photoresist composition comprising a photoacid generator and a polymer comprising acid-decomposable groups; (c) coating a pattern trimming composition of any of claims 1 to 9 over the photoresist pattern; (d) heating the coated photoresist pattern; and (e) rinsing the coated and heated photoresist pattern with a rinsing agent to remove a surface region of the photoresist pattern.

### BRIEF DESCRIPTION OF THE DRAWINGS

The present invention will be described with reference to the following drawing, in which like reference numerals denote like features, and in which:

FIG. 1A-H illustrates an exemplary process flow for forming a pattern in accordance with the invention.

### DETAILED DESCRIPTION OF THE INVENTION

The terminology used herein is for the purpose of describing particular embodiments only and is not intended to be limiting of the invention. The singular forms “a”, “an” and “the” are intended to include singular and plural forms, unless the context indicates otherwise. All ranges disclosed herein are inclusive of the endpoints, and the endpoints are independently combinable with each other. When an element is referred to as being “on” or “over” another element, it may be directly in contact with the other element or intervening elements may be present therebetween. In contrast, when an element is referred to as being “directly on” another element, there are no intervening elements present.

As used herein, an “acid-decomposable group” refers to a group in which a bond is cleaved by the catalytic action of an acid, optionally and typically with thermal treatment, resulting in a polar group, for example, a carboxylic acid or an alcohol group, being formed on the polymer, and optionally and typically with a moiety connected to the cleaved bond becoming disconnected from the polymer. Acid-decomposable groups include, for example: tertiary alkyl ester groups, secondary or tertiary aryl ester groups, secondary or tertiary ester groups having a combination of alkyl and aryl groups, tertiary alkoxy groups, acetal groups, or ketal groups. Acid-decomposable groups are also commonly referred to in the art as “acid-cleavable groups,” “acid-cleavable protecting groups,” “acid-labile groups,” “acid-labile protecting groups,” “acid-leaving groups,” and “acid-sensitive groups.”

Unless otherwise indicated, a group that is “substituted” refers to a group having one or more of its hydrogen atoms replaced with one or more substituents. Exemplary substituent groups include, but are not limited to, hydroxy (—OH), halogen (e.g., —F, —I, —Br), C₁₋₁₈ alkyl, C₁₋₈ haloalkyl, C₃₋₁₂ cycloalkyl, C₆₋₁₂ aryl having at least one aromatic ring (e.g., phenyl, biphenyl, naphthyl, or the like, each ring either substituted or unsubstituted aromatic), C₇₋₁₉ arylalkyl having at least one aromatic ring, C₇₋₁₂ alkylaryl, and combinations thereof. For purposes of carbon number determination, when a group is substituted, the number of carbon atoms of the group is the total number of carbon atoms in such group excluding those of any substituents.

### Photoresist Pattern Trimming Compositions

Photoresist pattern trimming compositions of the invention include a polymer comprising as polymerized units a monomer comprising an acid-decomposable group, the decomposition of which group forms a carboxylic acid group on the polymer, a non-polymeric acid or a non-polymeric thermal acid generator, and an organic-based solvent system comprising one or more organic solvents, and can include one or more optional additional components.

The polymer allows for the compositions to be coated over a photoresist pattern in the form of a layer having a desired thickness. The polymer should have good solubility in the organic-based solvent system of the trimming composition. The polymer should also have good solubility in the rinsing agent to be used in the patterning process. For example, the polymer can be soluble in an aqueous alkaline solution such as those typically used as photoresist developers, preferably aqueous quaternary ammonium hydroxide solutions such as aqueous tetramethylammonium hydroxide (TMAH) solutions. To minimize residue defects originating from the pattern trimming composition, the dissolution rate of a dried layer of the trimming composition in a rinsing agent to be applied should be greater than that of the photoresist pattern in the rinsing agent. The polymer typically exhibits a dissolution rate in the rinsing agent, preferably a 0.26N TMAH solution, of 100 Å/second or higher, preferably 1000 Å/second or higher. The polymer is preferably free of strong acid groups such as sulfonic acid (—SO₃H) and carboxylic acid (—CO₂H) groups as such groups typically reduce solubility of the polymer in non-polar solvents of the trimming composition. In certain aspects, the polymer may also be free of fluoroalkyl and/or fluoroalcohol groups.

The acid decomposable group which, on decomposition, forms a carboxylic acid group on the polymer is preferably a tertiary ester group of the formula —C(O)OC(R¹)₃ or an acetal group of the formula —C(O)OC(R²)₂OR³, wherein: R¹ is each independently linear C₁₋₂₀ alkyl, branched C₃₋₂₀ alkyl, monocyclic or polycyclic C₃₋₂₀ cycloalkyl, linear C₂₋₂₀ alkenyl, branched C₃₋₂₀ alkenyl, monocyclic or polycyclic C₃₋₂₀ cycloalkenyl, monocyclic or polycyclic C₆₋₂₀ aryl, or monocyclic or polycyclic C₂₋₂₀ heteroaryl, preferably linear C₁₋₆ alkyl, branched C₃₋₆ alkyl, or monocyclic or polycyclic C₃₋₁₀ cycloalkyl, each of which is substituted or unsubstituted, each R¹ optionally including as part of its structure one or more groups chosen from —O—, —C(O)—, —C(O)—O—, or —S—, and any two R¹ groups together optionally forming a ring; R² is independently hydrogen, fluorine, linear C₁₋₂₀ alkyl, branched C₃₋₂₀ alkyl, monocyclic or polycyclic C₃₋₂₀ cycloalkyl, linear C₂₋₂₀ alkenyl, branched C₃₋₂₀ alkenyl, monocyclic or polycyclic C₃₋₂₀ cycloalkenyl, monocyclic or polycyclic C₆₋₂₀ aryl, or monocyclic or polycyclic C₂₋₂₀ heteroaryl, preferably hydrogen, linear C₁₋₆ alkyl, branched C₃₋₆ alkyl, or monocyclic or polycyclic C₃₋₁₀ cycloalkyl, each of which is substituted or unsubstituted, each R² optionally including as part of its structure one or more groups chosen from —O—, —C(O)—, —C(O)—O—, or —S—, and the R² groups together optionally forming a ring; and R³ is linear C₁₋₂₀ alkyl, branched C₃₋₂₀ alkyl, monocyclic or polycyclic C₃₋₂₀ cycloalkyl, linear C₂₋₂₀ alkenyl, branched C₃₋₂₀ alkenyl, monocyclic or polycyclic C₃₋₂₀ cycloalkenyl, monocyclic or polycyclic C₆₋₂₀ aryl, or monocyclic or polycyclic C₂₋₂₀ heteroaryl, preferably linear C₁₋₆ alkyl, branched C₃₋₆ alkyl, or monocyclic or polycyclic C₃₋₁₀ cycloalkyl, each of which is substituted or unsubstituted, R³ optionally including as part of its structure one or more groups chosen from —O—, —C(O)—, —C(O)—O—, or —S—, and one R² together with R³ optionally forming a ring. Such monomer is typically a vinyl aromatic, (meth)acrylate, or norbornyl monomer.

Suitable monomers comprising such an acid-decomposable group include monomers of the following formulas (1a), (1b), (1c), and (1d):

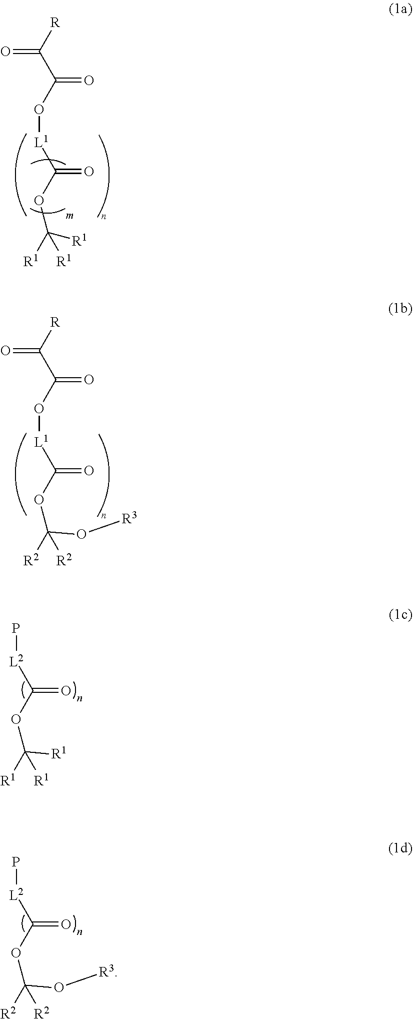

wherein: R is hydrogen, fluorine, C₁₋₅ alkyl, or C₁₋₅ fluoroalkyl, typically hydrogen or methyl; R¹, R², and R³ are as defined above; L¹ is a single bond or an m+1-valent linking group comprising at least one carbon atom, typically C₁₋₁₀ linear, C₃₋₁₀ branched, or C₃₋₁₀ cyclic, each of which may be substituted or unsubstituted, and may include one or more heteroatoms; P is a polymerizable group selected from vinyl or norbornyl; L² is a single bond or a divalent linking group comprising at least one carbon atom, typically C₁₋₁₀ linear, C₃₋₁₀ branched, or C₃₋₁₀ cyclic, each of which may be substituted or unsubstituted, and may include one or more heteroatoms, provided that L² is not a single bond when P is vinyl; m is 1 or 2; and n is 0 or 1.

Suitable such monomers comprising an acid-decomposable group include, for example, the following:

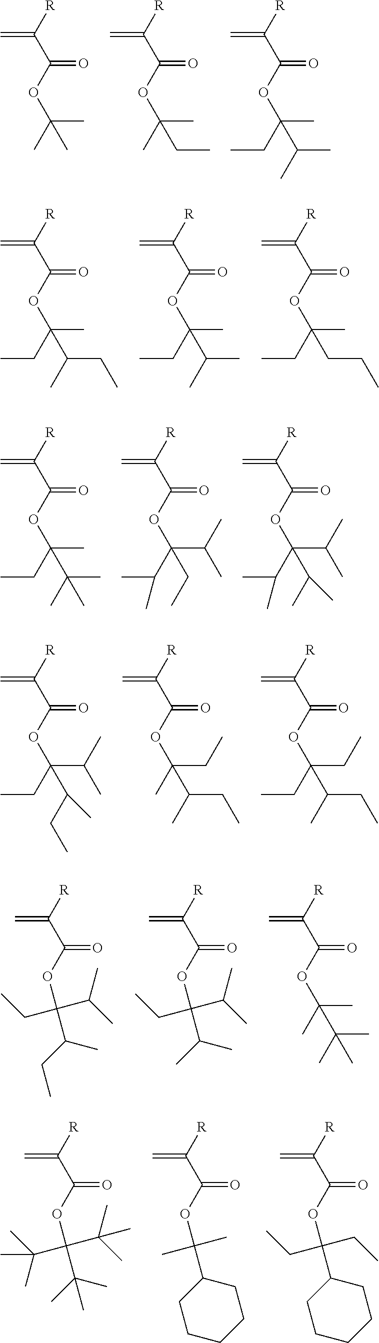

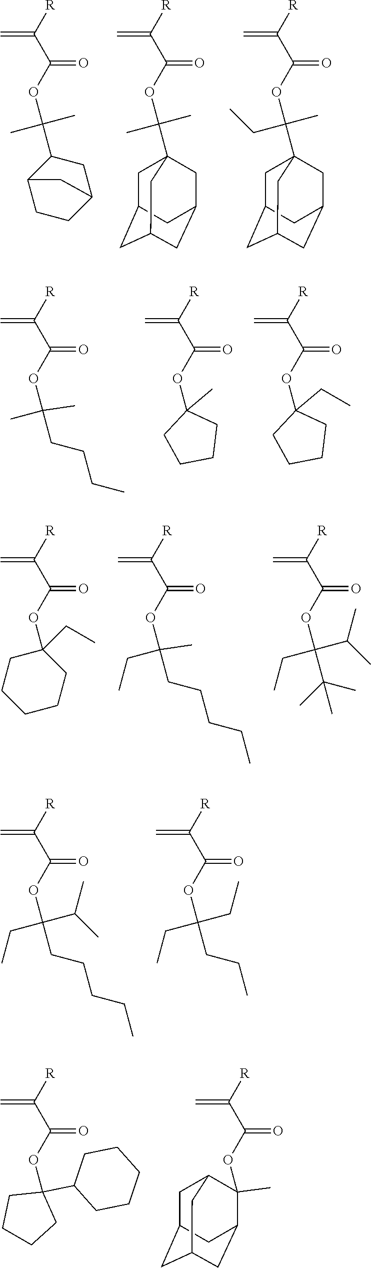

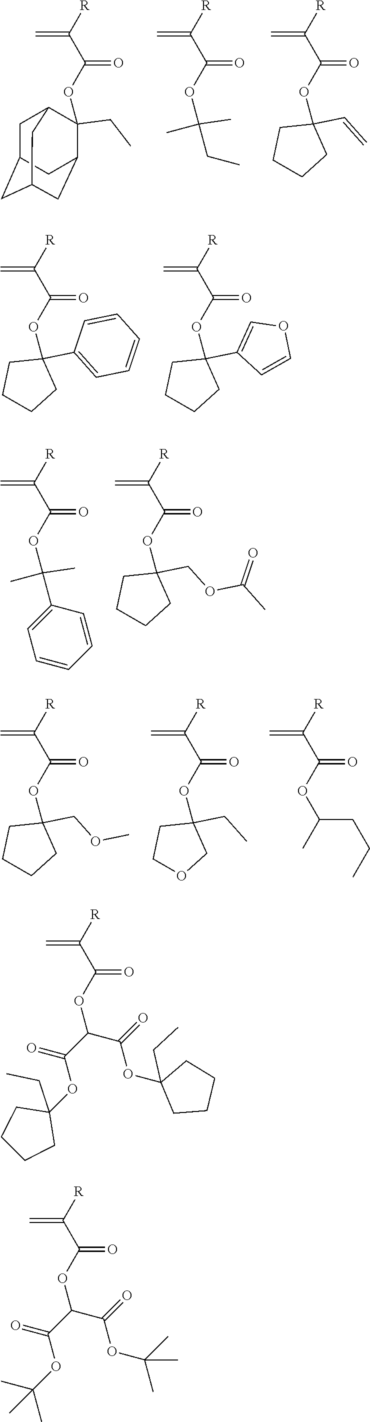

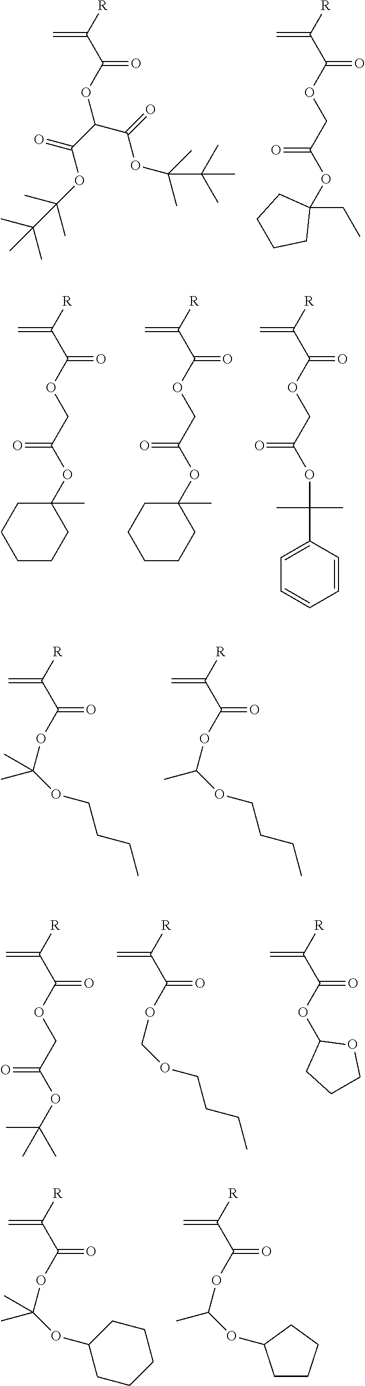

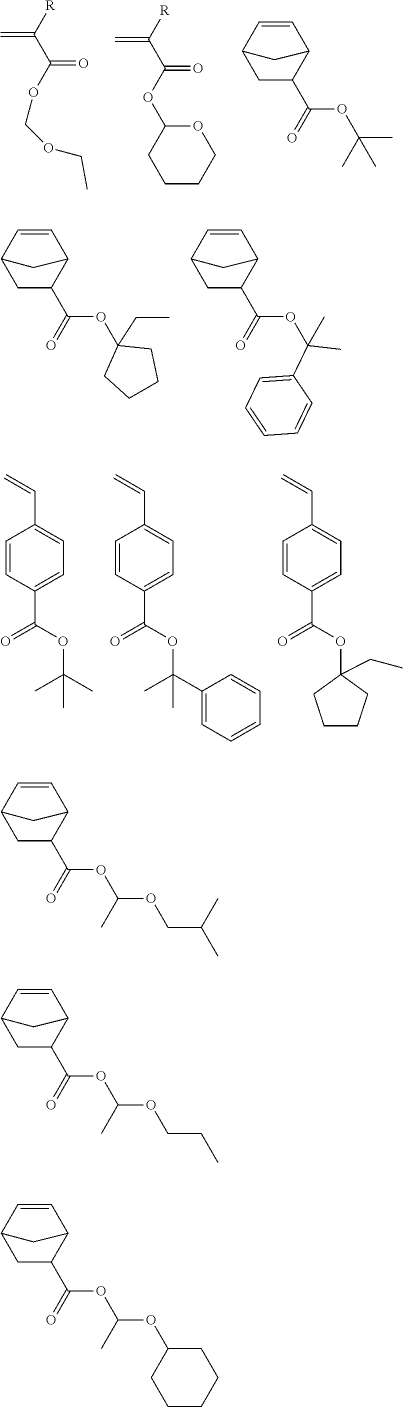

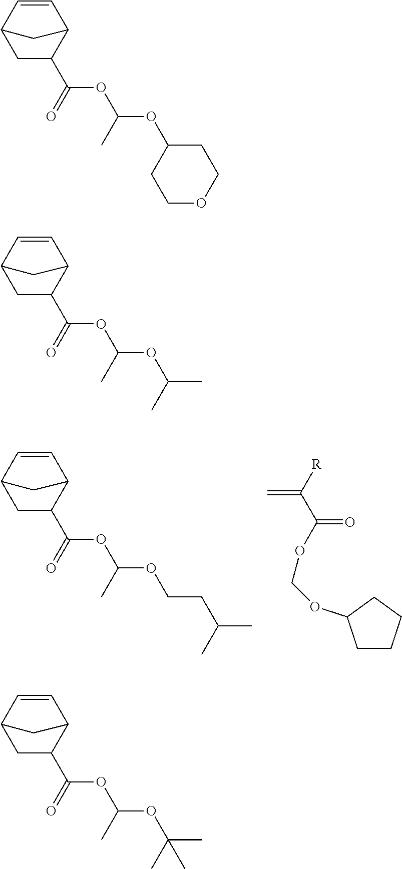

wherein R is as defined above. The total content of polymerized units comprising an acid-decomposable group which forms a carboxylic acid group on the polymer is typically from 10 to 100 mole %, more typically from 10 to 90 mole % or from 30 to 70 mole %, based on total polymerized units of the polymer.

The polymer can further include as polymerized a monomer comprising an acid-decomposable group, the decomposition of which group forms an alcohol group or a fluoroalcohol group on the polymer. Suitable such groups include, for example, an acetal group of the formula —COC(R²)₂OR³—, or a carbonate ester group of the formula —OC(O)O—. Such monomer is typically a vinyl aromatic, (meth)acrylate, or norbornyl monomers.

Suitable monomers comprising an acid-decomposable group that forms an alcohol or fluoroalcohol group include, for example, the following:

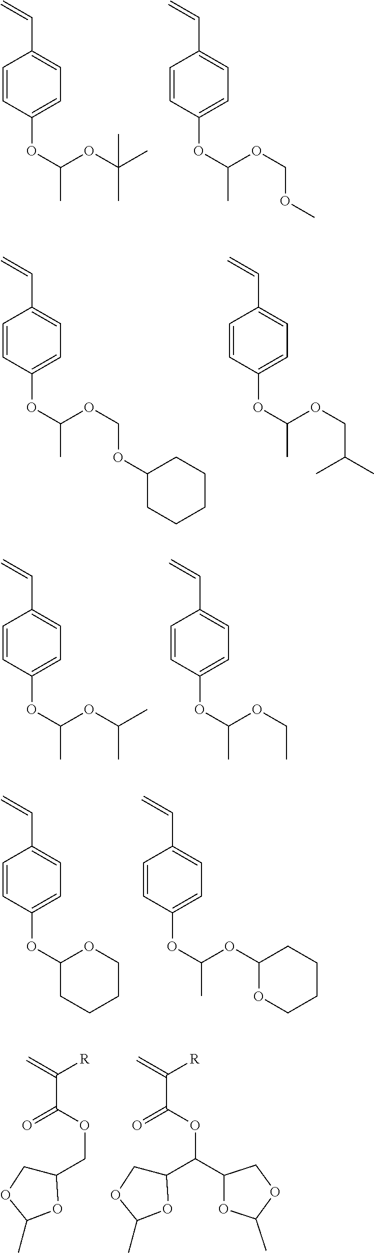

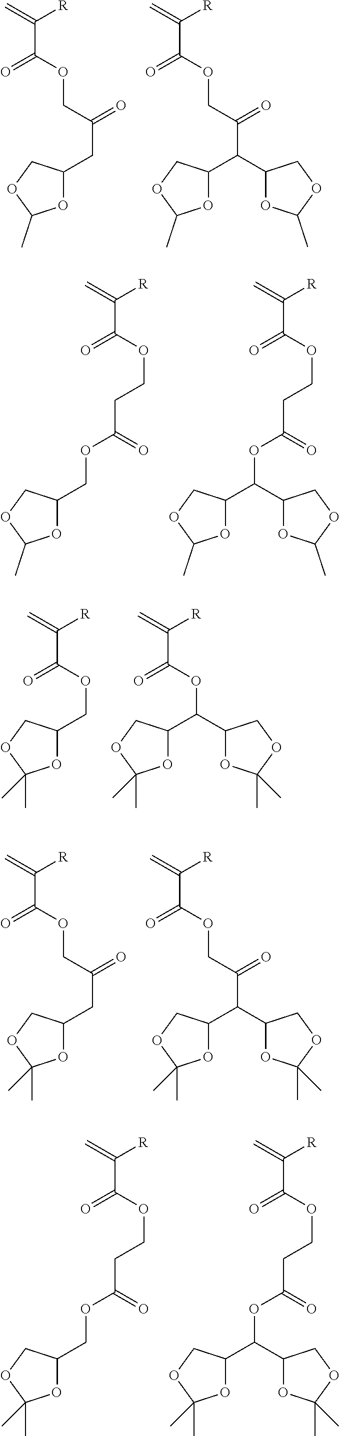

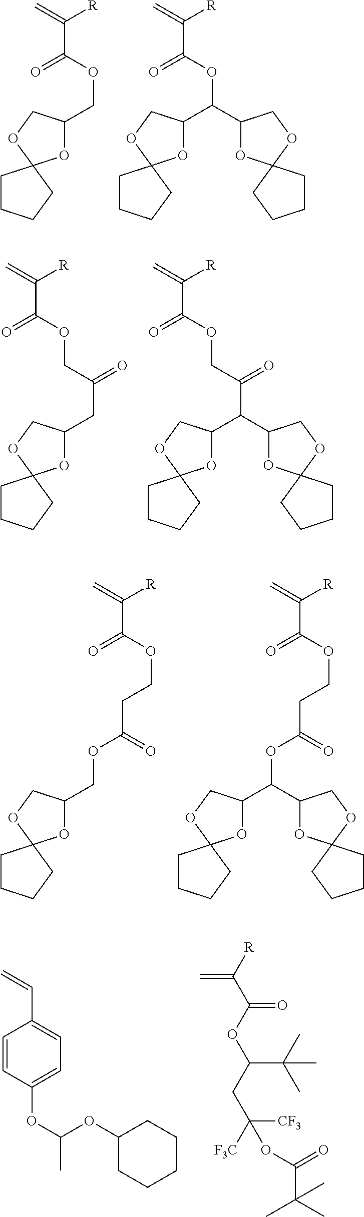

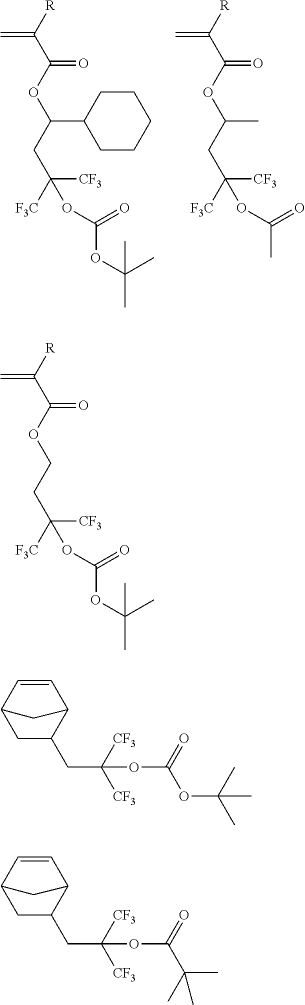

wherein R is as defined above. If present in the polymer, the total content of polymerized units comprising an acid-decomposable group, the decomposition of which group forms an alcohol group or a fluoroalcohol group on the polymer, is typically from 10 to 90 mole %, more typically from 30 to 70 mole %, based on total polymerized units of the polymer.

The polymer preferably further includes as polymerized a neutral, solubility enhancing monomer. Such monomer is typically a vinyl aromatic, (meth)acrylate, or norbornyl monomer. Suitable neutral, solubility enhancing monomers include, for example, the following:

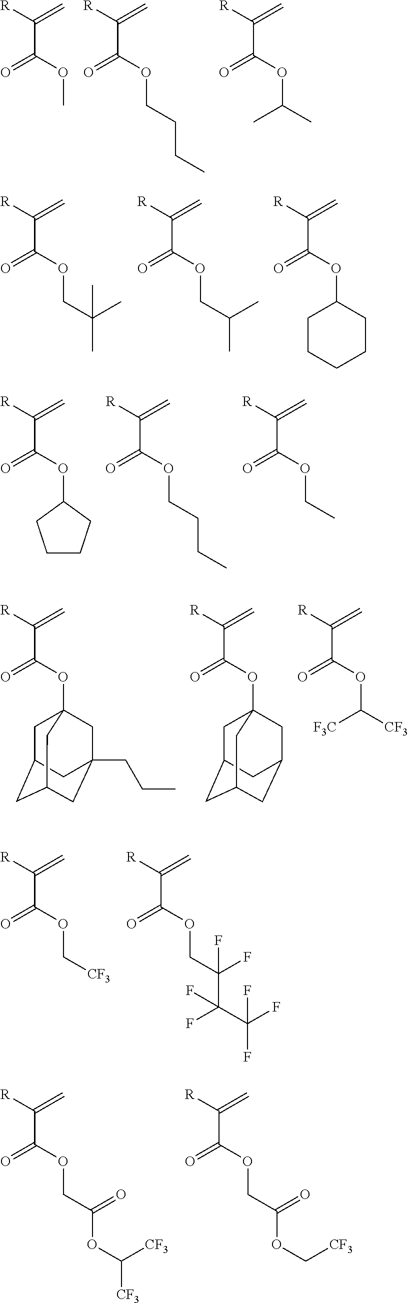

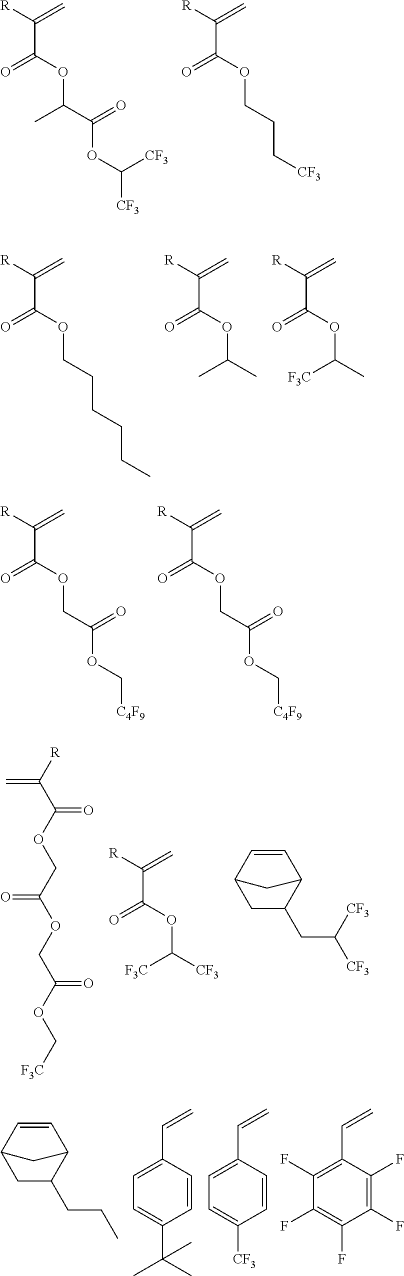

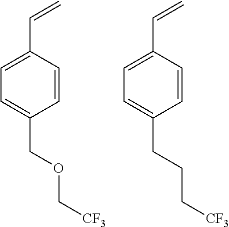

wherein R is as defined above. If present in the polymer, the total content of polymerized units of neutral, solubility enhancing monomers is typically from 10 to 90 mole %, more typically from 30 to 70 mole %, based on total polymerized units of the polymer.

The polymer can include one or more additional types of polymerized units. Suitable additional units can contain groups chosen, for example, from one or more of alkyl, hydroxy, fluoroalkyl, fluoroalcohol, ester, ether, imide, sulfonamide, oxoalkanoate groups, and combinations thereof. Such additional units are typically formed from monomers chosen, for example, from vinyl aromatic, (meth)acrylate, or norbornyl monomers. Exemplary suitable such additional monomers include the following:

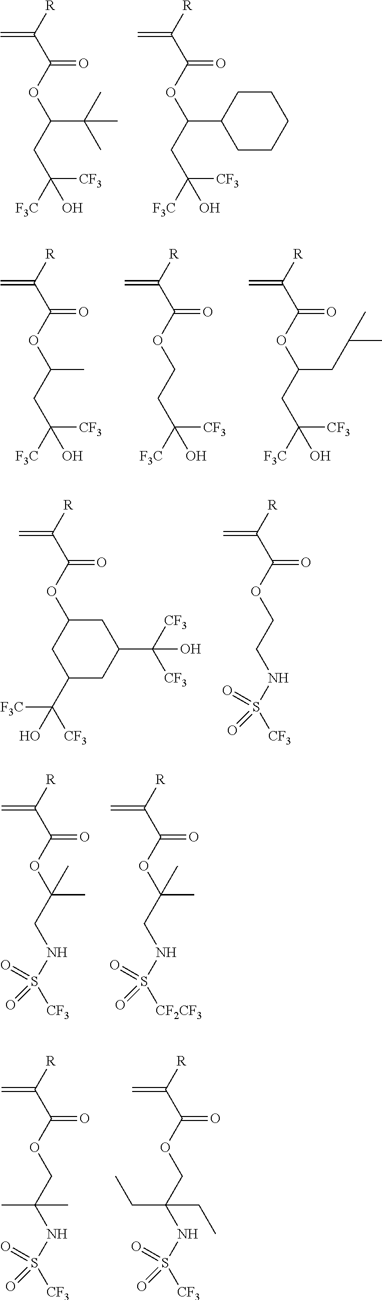

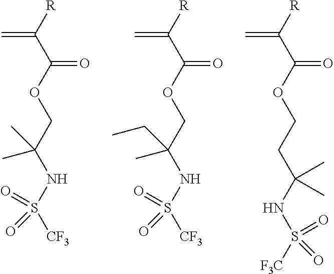

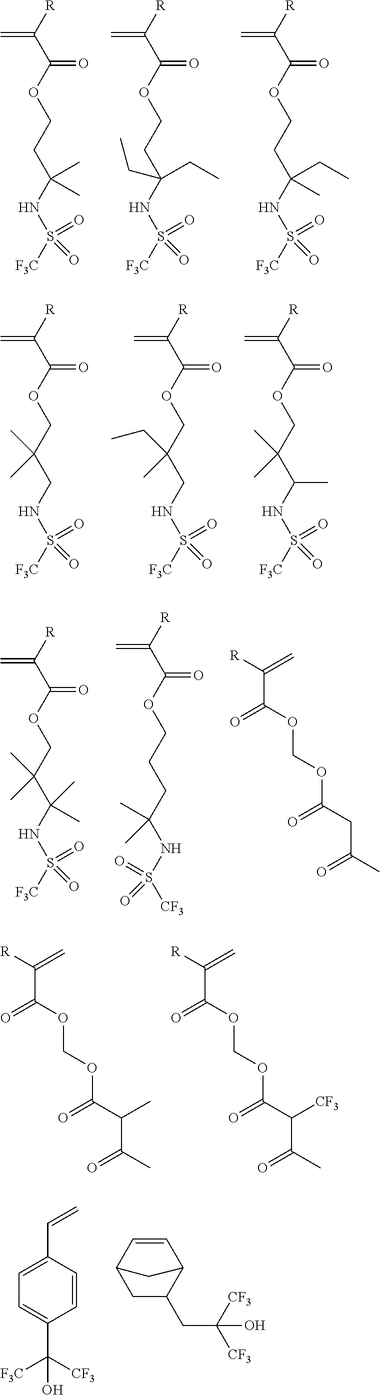

wherein K is as defined above. If present in me polymer, me content of such additional polymerized units can vary widely, and may, for example, each be present in an amount from 2 to 20 mole % based on total polymerized units of the polymer.

Suitable polymers in accordance with the invention include homopolymers or copolymers comprising two, three, or more distinct repeating units. Suitable homopolymers include polymerized units formed from a monomer as described above that comprises an acid-decomposable group which forms a carboxylic acid. Suitable copolymers include, for example, the following:

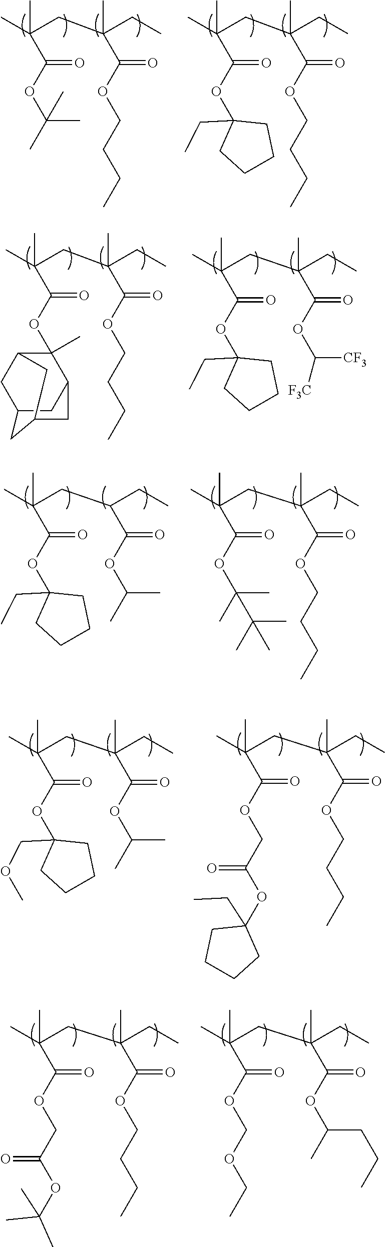

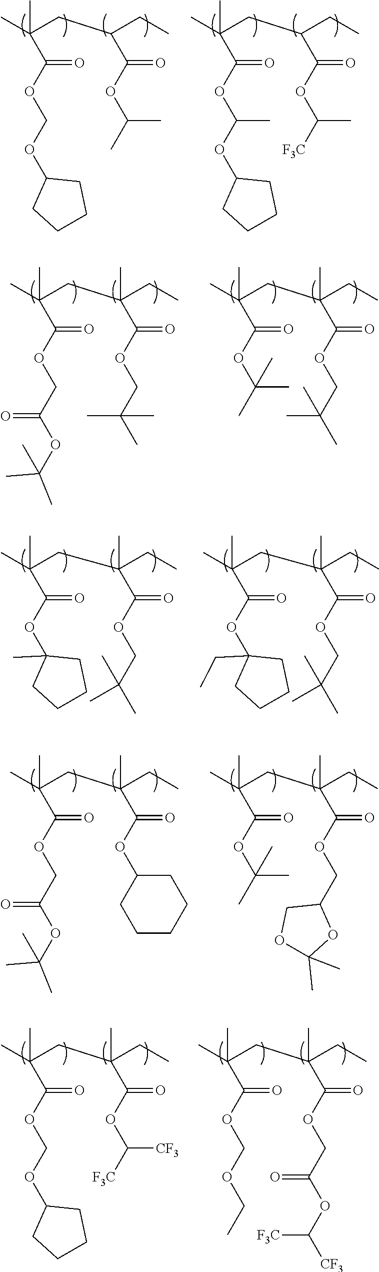

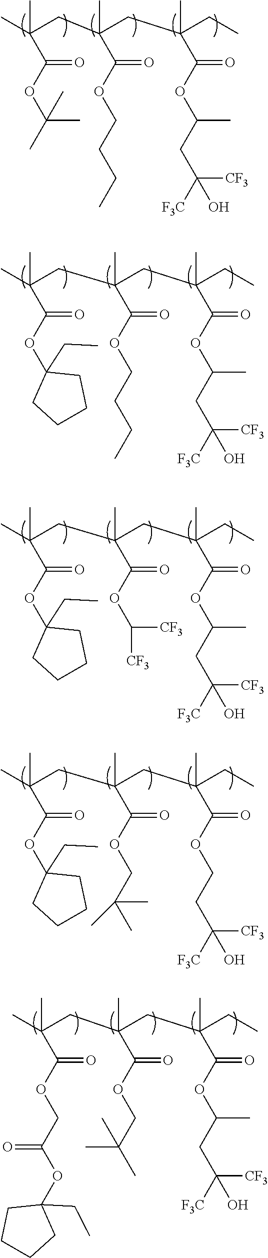

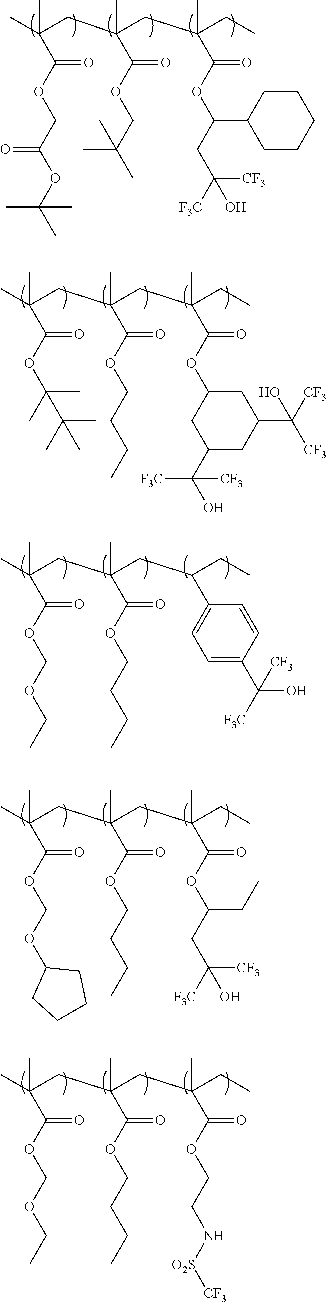

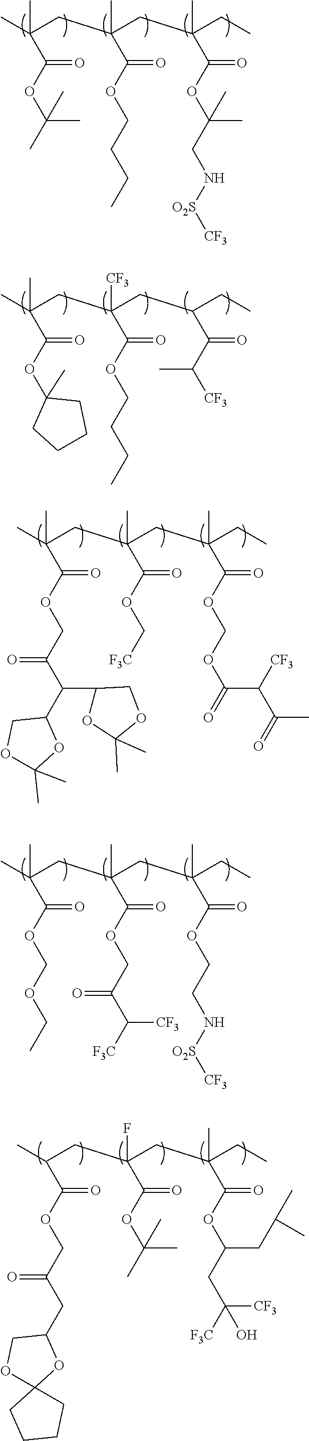

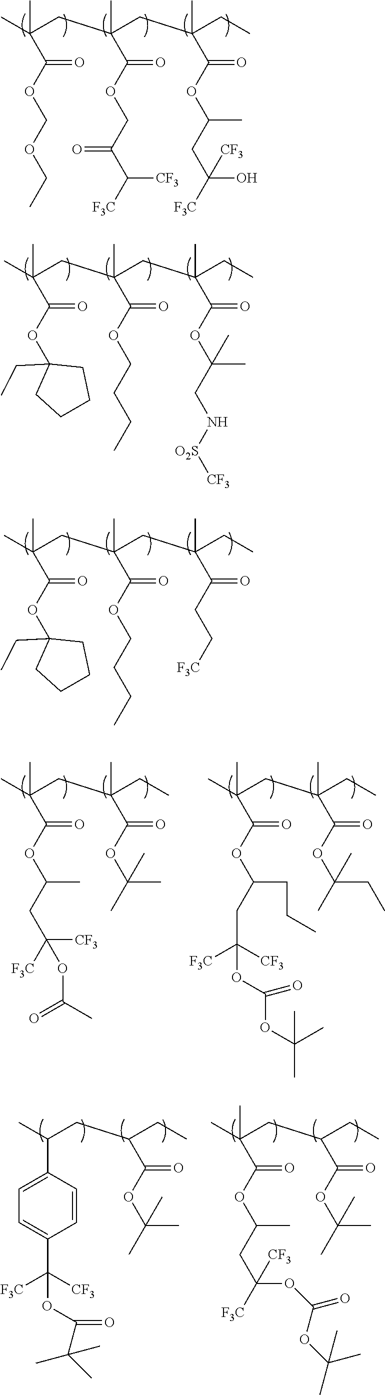

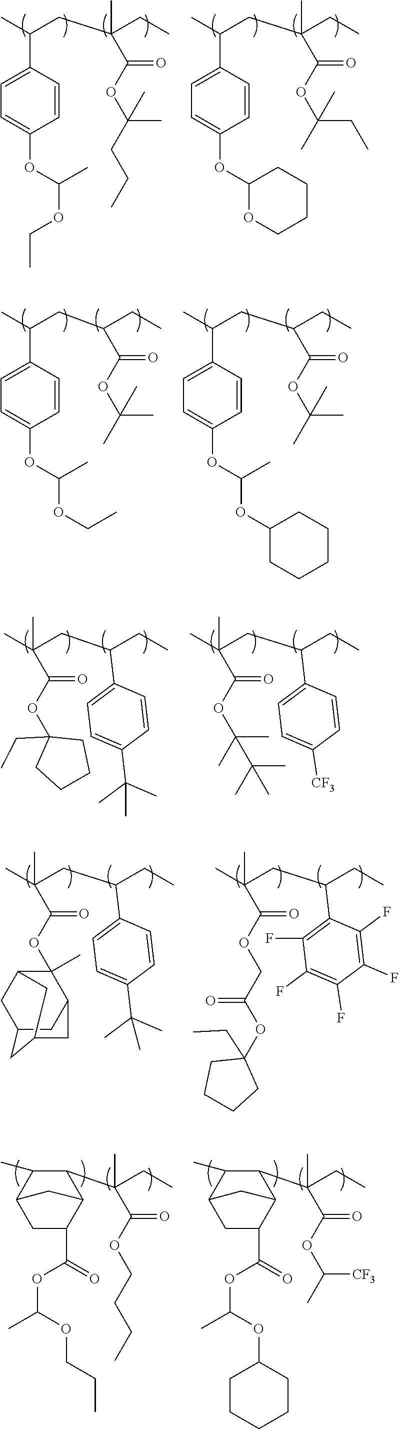

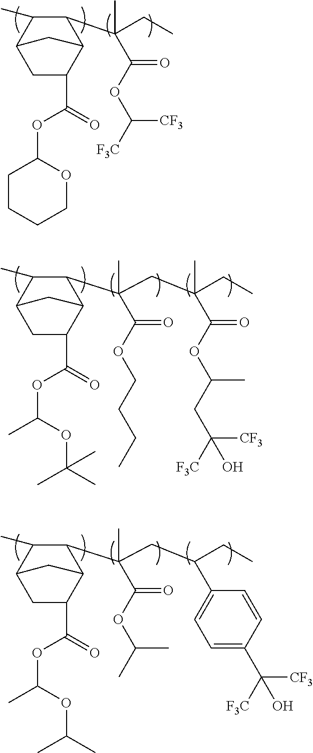

wherein the molar ratios of the units in each polymer add up to 100 mol % and may be selected in ranges such as described above.

The trimming compositions typically include a single polymer, but can optionally include one or more additional polymers. The content of the polymer in the composition will depend, for example, on the target thickness of the layer, with a higher polymer content being used when a thicker layer is desired. The polymer is typically present in the pattern trimming composition in an amount of from 80 to 99.9 wt %, more typically from 90 to 99 wt %, or 95 to 99 wt %, based on total solids of the trimming composition. The weight average molecular weight (Mw) of the polymer is typically less than 400,000, preferably from 3000 to 50,000, more preferably from 3000 to 25,000, as measured by GPC versus polystyrene standards. Typically, the polymer will have a polydispersity index (PDI=Mw/Mn) of 3 or less, preferably 2 or less, with Mw and Mn measured by GPC versus polystyrene standards.

Suitable polymers for use in the trimming compositions are commercially available and/or can readily be made by persons skilled in the art. For example, the polymer may be synthesized by dissolving selected monomers corresponding to units of the polymer in an organic solvent, adding a radical polymerization initiator thereto, and effecting heat polymerization to form the polymer. Examples of suitable organic solvents that can be used for polymerization of the polymer include, for example, toluene, benzene, tetrahydrofuran, diethyl ether, dioxane, ethyl lactate and methyl isobutyl carbinol. Suitable polymerization initiators include, for example, 2,2′-azobisisobutyronitrile (AIBN), 2,2′-azobis(2,4-dimethylvaleronitrile), dimethyl 2,2-azobis(2-methylpropionate), benzoyl peroxide and lauroyl peroxide.

The trimming compositions further include a non-polymeric acid or a non-polymeric thermal acid generator (TAG). The acid or generated acid in the case of a TAG should be sufficient with heat to cause cleavage of the bonds of acid-decomposable groups of the polymer in a surface region of the photoresist pattern to cause increased solubility of the photoresist polymer in a rinsing solution to be applied. The acid or TAG is in non-polymeric form to better allow diffusion into the photoresist pattern during processing as compared with polymeric acids and TAGs. The trimming compositions are preferably free of polymeric acids and polymeric TAGs. The non-polymeric acid or non-polymeric TAG is typically present in the composition in an amount of from about 0.01 to 20 wt % based on the total solids of the trimming composition.

Preferable non-polymeric acids are organic acids including non-aromatic acids and aromatic acids, each of which can optionally have fluorine substitution. Suitable organic acids include, for example: carboxylic acids such as alkanoic acids, including formic acid, acetic acid, propionic acid, butyric acid, dichloroacetic acid, trichloroacetic acid, perfluoroacetic acid, perfluorooctanoic acid, oxalic acid malonic acid and succinic acid; hydroxyalkanoic acids, such as citric acid; aromatic carboxylic acids such as benzoic acid, fluorobenzoic acid, hydroxybenzoic acid and naphthoic acid; organic phosphorus acids such as dimethylphosphoric acid and dimethylphosphinic acid; and sulfonic acids such as optionally fluorinated alkylsulfonic acids including methanesulfonic acid, trifluoromethanesulfonic acid, ethanesulfonic acid, 1-butanesulfonic acid, 1-perfluorobutanesulfonic acid, 1,1,2,2-tetrafluorobutane-1-sulfonic acid, 1,1,2,2-tetrafluoro-4-hydroxybutane-1-sulfonic acid, 1-pentanesulfonic acid, 1-hexanesulfonic acid, and 1-heptanesulfonic acid.

Suitable TAGs include those capable of generating a non-polymeric acid as described above. The TAG can be non-ionic or ionic. Suitable nonionic thermal acid generators include, for example, cyclohexyl trifluoromethyl sulfonate, methyl trifluoromethyl sulfonate, cyclohexyl p-toluenesulfonate, methyl p-toluenesulfonate, cyclohexyl 2,4,6-triisopropylbenzene sulfonate, nitrobenzyl esters, benzoin tosylate, 2-nitrobenzyl tosylate, tris(2,3-dibromopropyl)-1,3,5-triazine-2,4,6-trione, alkyl esters of organic sulfonic acids, p-toluenesulfonic acid, dodecylbenzenesulfonic acid, oxalic acid, phthalic acid, phosphoric acid, camphorsulfonic acid, 2,4,6-trimethylbenzene sulfonic acid, triisopropylnaphthalene sulfonic acid, 5-nitro-o-toluene sulfonic acid, 5-sulfosalicylic acid, 2,5-dimethylbenzene sulfonic acid, 2-nitrobenzene sulfonic acid, 3-chlorobenzene sulfonic acid, 3-bromobenzene sulfonic acid, 2-fluorocaprylnaphthalene sulfonic acid, dodecylbenzene sulfonic acid, 1-naphthol-5-sulfonic acid, 2-methoxy-4-hydroxy-5-benzoyl-benzene sulfonic acid, and their salts, and combinations thereof. Suitable ionic thermal acid generators include, for example, dodecylbenzenesulfonic acid triethylamine salts, dodecylbenzenedisulfonic acid triethylamine salts, p-toluene sulfonic acid-ammonium salts, p-toluene sulfonic acid-pyridinium salts, sulfonate salts, such as carbocyclic aryl and heteroaryl sulfonate salts, aliphatic sulfonate salts, and benzenesulfonate salts. Compounds that generate a sulfonic acid upon activation are generally suitable. Preferred thermal acid generators include p-toluenesulfonic acid ammonium salts, and heteroaryl sulfonate salts.

Preferably, the TAG is ionic with a reaction scheme for generation of a sulfonic acid as shown below:

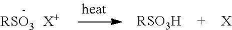

wherein RSO₃⁻ is the TAG anion and X⁺ is the TAG cation, preferably an organic cation. The cation can be a nitrogen-containing cation of the general formula (I):

(BH)⁺ (I)

which is the monoprotonated form of a nitrogen-containing base B. Suitable nitrogen-containing bases B include, for example: optionally substituted amines such as ammonia, difluoromethylammonia, C1-20 alkyl amines, and C3-30 aryl amines, for example, nitrogen-containing heteroaromatic bases such as pyridine or substituted pyridine (e.g., 3-fluoropyridine), pyrimidine and pyrazine; nitrogen-containing heterocyclic groups, for example, oxazole, oxazoline, or thiazoline. The foregoing nitrogen-containing bases B can be optionally substituted, for example, with one or more group chosen from alkyl, aryl, halogen atom (preferably fluorine), cyano, nitro and alkoxy. Of these, base B is preferably a heteroaromatic base.

Base B typically has a pKa from 0 to 5.0, or between 0 and 4.0, or between 0 and 3.0, or between 1.0 and 3.0. As used herein, the term “pKₐ” is used in accordance with its art-recognized meaning, that is, pKₐ is the negative log (to the base 10) of the dissociation constant of the conjugate acid (BH)⁺ of the basic moiety (B) in aqueous solution at about room temperature. In certain embodiments, base B has a boiling point less than about 170° C., or less than about 160° C., 150° C., 140° C., 130° C., 120° C., 110° C., 100° C. or 90° C.

Exemplary suitable nitrogen-containing cations (BH)⁺ include NH₄⁺, CF₂HNH₂⁺, CF₃CH₂NH₃⁺, (CH₃)₃NH⁺, (C₂H₅)₃NH⁺, (CH₃)₂(C₂H₅)NH⁺ and the following:

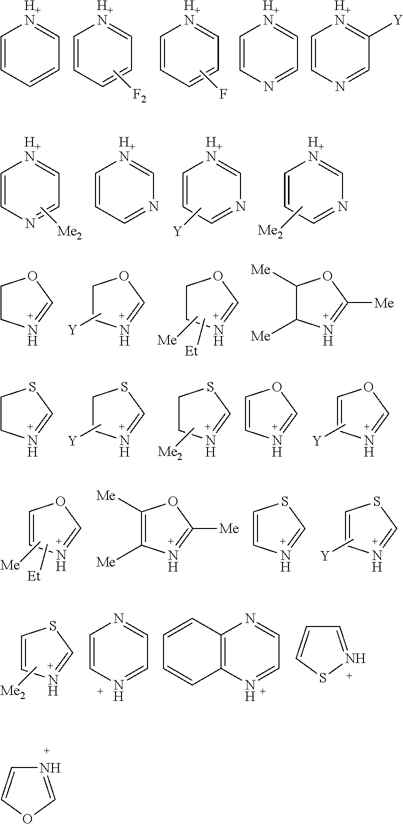

in which Y is alkyl, preferably, methyl or ethyl.

The trimming compositions further include an organic-based solvent system comprising one or more organic solvents. The term “organic-based” means that the solvent system includes greater than 50 wt % organic solvent based on total solvents of the trimming composition, more typically greater than 90 wt %, greater than 95 wt %, greater than 99 wt % or 100 wt % organic solvents, based on total solvents of the trimming compositions. Suitable solvent materials to formulate and cast the trimming compositions should exhibit good solubility characteristics with respect to the non-solvent components of the trimming composition, without appreciably dissolving the underlying photoresist pattern, so as to minimize intermixing with the photoresist pattern.

When the photoresist pattern to be trimmed is formed from a vinyl aromatic-based polymer, such as a polymer containing styrene or hydroxystyrene units, as is typical for KrF and EUV photoresists, the solvent system preferably comprises one or more non-polar organic solvents. Preferably, the solvent system is non-polar organic-based. The term “non-polar organic-based” means that the solvent system includes greater than 50 wt % of combined non-polar organic solvents based on total solvents of the trimming composition, more typically greater than 70 wt %, greater than 85 wt % or 100 wt %, combined non-polar organic solvents, based on total solvents of the trimming composition. The non-polar organic solvents are typically present in the solvent system in a combined amount of from 70 to 98 wt %, preferably 80 to 95 wt %, more preferably from 85 to 98 wt %, based on the solvent system. It is believed that use of a non-polar organic-based solvent system can provide low top-loss characteristics when treating vinyl aromatic-based photoresist patterns. As used herein, “vinyl aromatic” means polymerized units formed from monomers in which an aromatic group is bonded directly to a vinyl group, for example, styrene, hydroxystyrene and vinyl naphthalene. “Vinyl aromatic-based polymer” means that the polymer contains greater than 50 mole % vinyl aromatic units based on total units of the polymer, more typically from 60 to 100 mole %, or from 80 to 100 mole %, based on total units of the polymer.

Suitable non-polar solvents include, for example, ethers, hydrocarbons, and combinations thereof, with ethers being preferred. Suitable ether solvents include, for example, alkyl monoethers and aromatic monoethers, particularly preferred of which are those having a total carbon number of from 6 to 16. Suitable alkyl monoethers include, for example, 1,4-cineole, 1,8-cineole, pinene oxide, di-n-propyl ether, diisopropyl ether, di-n-butyl ether, di-n-pentyl ether, diisoamyl ether, dihexyl ether, diheptyl ether, and dioctyl ether, with diisoamyl ether being preferred. Suitable aromatic monoethers include, for example, anisole, ethylbenzyl ether, diphenyl ether, dibenzyl ether and phenetole, with anisole being preferred. Suitable aliphatic hydrocarbons include, for example, n-heptane, 2-methylheptane, 3-methylheptane, 3,3-dimethylhexane, 2,3,4-trimethylpentane, n-octane, n-nonane, n-decane, and fluorinated compounds such as perfluoroheptane. Suitable aromatic hydrocarbons include, for example, benzene, toluene, and xylene.

The solvent system preferably further includes one or more alcohol and/or ester solvents. For certain trimming compositions, an alcohol and/or ester solvent may provide enhanced solubility with respect to the solid components of the trimming composition. Suitable alcohol solvents include, for example: straight, branched or cyclic C₄₋₉ monohydric alcohol such as 1-butanol, 2-butanol, isobutyl alcohol, tert-butyl alcohol, 3-methyl-1-butanol, 1-pentanol, 2-pentanol, 4-methyl-2-pentanol, 1-hexanol, 1-heptanol, 1-octanol, 2-hexanol, 2-heptanol, 2-octanol, 3-hexanol, 3-heptanol, 3-octanol, 4-octanol, 2,2,3,3,4,4-hexafluoro-1-butanol, 2,2,3,3,4,4,5,5-octafluoro-1-pentanol, and 2,2,3,3,4,4,5,5,6,6-decafluoro-1-hexanol; and C₅₋₉ fluorinated diols such as 2,2,3,3,4,4-hexafluoro-1,5-pentanediol, 2,2,3,3,4,4,5,5-octafluoro-1,6-hexanediol, and 2,2,3,3,4,4,5,5,6,6,7,7-dodecafluoro-1,8-octanediol. The alcohol solvent is preferably a C₄₋₉ monohydric alcohol, with 4-methyl-2-pentanol being preferred. Suitable ester solvents include, for example, alkyl esters having a total carbon number of from 4 to 10, for example, alkyl propionates such as n-butyl propionate, n-pentyl propionate, n-hexyl propionate, and n-heptyl propionate, and alkyl butyrates such as n-butyl butyrate, isobutyl butyrate, and isobutyl isobutyrate. The one or more alcohol and/or ester solvents if used in the solvent system are typically present in a combined amount of from 2 to 50 wt %, more typically in an amount of from 2 to 30 wt %, based on the solvent system.

The solvent system can include one or more additional solvents chosen, for example, from one or more of: ketones such as 2,5-dimethyl-4-hexanone and 2,6-dimethyl-4-heptanone; and polyethers such as dipropylene glycol monomethyl ether and tripropylene glycol monomethyl ether. Such additional solvents, if used, are typically present in a combined amount of from 1 to 20 wt % based on the solvent system.

A particularly preferred organic-based solvent system includes one or more monoether solvents in a combined amount of from 70 to 98 wt % based on the solvent system, and one or more alcohol and/or ester solvents in a combined amount of from 2 to 30 wt % based on the solvent system. The solvent system is typically present in the overcoat composition in an amount of from 90 to 99 wt %, preferably from 95 to 99 wt %, based on the overcoat composition.

The trimming composition can further include one or more additional, optional component, for example, a surfactant. Typical surfactants include those which exhibit an amphiphilic nature, meaning that they can be both hydrophilic and hydrophobic at the same time. Amphiphilic surfactants possess a hydrophilic head group or groups, which have a strong affinity for water and a long hydrophobic tail, which is organophilic and repels water. Suitable surfactants can be ionic (i.e., anionic, cationic) or nonionic. Further examples of surfactants include silicone surfactants, poly(alkylene oxide) surfactants, and fluorochemical surfactants. Suitable non-ionic surfactants include, but are not limited to, octyl and nonyl phenol ethoxylates such as TRITON® X-114, X-100, X-45, X-15 and branched secondary alcohol ethoxylates such as TERGITOL™ TMN-6 (The Dow Chemical Company, Midland, Mich. USA). Still further exemplary surfactants include alcohol (primary and secondary) ethoxylates, amine ethoxylates, glucosides, glucamine, polyethylene glycols, poly(ethylene glycol-co-propylene glycol), or other surfactants disclosed in McCutcheon's Emulsifiers and Detergents, North American Edition for the Year 2000 published by Manufacturers Confectioners Publishing Co. of Glen Rock, N.J. Nonionic surfactants that are acetylenic diol derivatives also can be suitable. Such surfactants are commercially available from Air Products and Chemicals, Inc. of Allentown, Pa. and sold under the trade names of SURFYNOL® and DYNOL®. Additional suitable surfactants include other polymeric compounds such as the tri-block EO-PO-EO co-polymers PLURONIC® 25R2, L121, L123, L31, L81, L101 and P123 (BASF, Inc.). Such surfactant and other optional additives if used are typically present in the composition in minor amounts such as from 0.01 to 10 wt % based on total solids of the trimming composition. The trimming compositions are preferably free of cross-linking agents and other materials that can result in a dimensional increase of the photoresist pattern.

The trimming compositions can be prepared following known procedures. For example, the compositions can be prepared by dissolving solid components of the composition in the solvent components. The desired total solids content of the compositions will depend on factors such as the desired final layer thickness. Preferably, the solids content of the trimming compositions is from 1 to 10 wt %, more preferably from 1 to 5 wt %, based on the total weight of the composition.

### Pattern Formation Methods

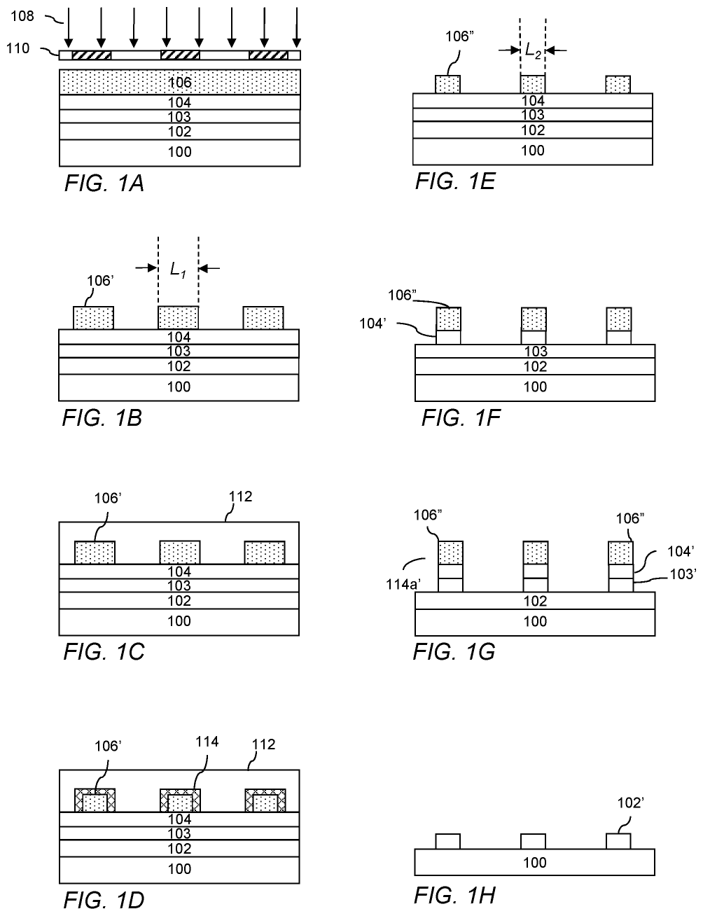

Processes in accordance with the invention will now be described with reference to FIG. 1A-H, which illustrates an exemplary process flow for a pattern formation method in accordance with the invention. While the illustrated process flow describes a patterning process in which a single resist mask is used to transfer the photoresist pattern to the underlying substrate, it should be clear that the method can be used in other lithographic processes, for example, in double patterning processes such as litho-litho-etch (LLE), litho-etch-litho-etch (LELE) or self-aligned double patterning (SADP), as an ion implantation mask, or any other lithographic process where such photoresist pattern treatment would be beneficial.

FIG. 1A depicts in cross-section a substrate 100 which may include various layers and features. The substrate can be of a material such as a semiconductor, such as silicon or a compound semiconductor (e.g., III-V or II-VI), glass, quartz, ceramic, copper and the like. Typically, the substrate is a semiconductor wafer, such as single crystal silicon or compound semiconductor wafer, and may have one or more layers and patterned features formed on a surface thereof. One or more layers to be patterned 102 may be provided over the substrate 100. Optionally, the underlying base substrate material itself may be patterned, for example, when it is desired to form trenches in the substrate material. In the case of patterning the base substrate material itself, the pattern shall be considered to be formed in a layer of the substrate.

The layers may include, for example, one or more conductive layers such as layers of aluminum, copper, molybdenum, tantalum, titanium, tungsten, alloys, nitrides or silicides of such metals, doped amorphous silicon or doped polysilicon, one or more dielectric layers such as layers of silicon oxide, silicon nitride, silicon oxynitride, or metal oxides, semiconductor layers, such as single-crystal silicon, and combinations thereof. The layers to be etched can be formed by various techniques, for example, chemical vapor deposition (CVD) such as plasma-enhanced CVD (PECVD), low-pressure CVD (LPCVD) or epitaxial growth, physical vapor deposition (PVD) such as sputtering or evaporation, or electroplating. The particular thickness of the one or more layers to be etched 102 will vary depending on the materials and particular devices being formed.

Depending on the particular layers to be etched, film thicknesses and photolithographic materials and process to be used, it may be desired to dispose over the layers 102 a hard mask layer 103 and/or a bottom antireflective coating (BARC) 104 over which a photoresist layer 106 is to be coated. Use of a hard mask layer may be desired, for example, with very thin resist layers, where the layers to be etched require a significant etching depth, and/or where the particular etchant has poor resist selectivity. Where a hard mask layer is used, the resist patterns to be formed can be transferred to the hard mask layer 103 which, in turn, can be used as a mask for etching the underlying layers 102. Suitable hard mask materials and formation methods are known in the art. Typical materials include, for example, tungsten, titanium, titanium nitride, titanium oxide, zirconium oxide, aluminum oxide, aluminum oxynitride, hafnium oxide, amorphous carbon, spin-on-carbon (SOC), silicon oxynitride and silicon nitride. The hard mask layer can include a single layer or a plurality of layers of different materials. The hard mask layer can be formed, for example, by CVD, PVD, or spin-coating techniques.

A bottom antireflective coating may be desirable where the substrate and/or underlying layers would otherwise reflect a significant amount of incident radiation during photoresist exposure such that the quality of the formed pattern would be adversely affected. Such coatings can improve depth-of-focus, exposure latitude, linewidth uniformity and CD control. Antireflective coatings are typically used where the resist is exposed to deep ultraviolet radiation (300 nm or less), for example, KrF (248 nm), ArF (193 nm) or EUV (13.5 nm) radiation. The antireflective coating can comprise a single layer or a plurality of different layers. Suitable antireflective materials and methods of formation are known in the art. Antireflective materials are commercially available, for example, those sold under the AR™ tradename by DuPont (Wilmington, Del. USA), such as AR™3, AR™40A and AR™124 antireflectant materials.

A photoresist layer 106 is formed from a photoresist composition, typically a chemically amplified photosensitive composition comprising a polymer having acid-labile groups, a photoacid generator and a solvent. Suitable photoresist compositions are well known in the art. Preferably, the photoresist polymers are formed from monomers chosen from vinyl aromatic (e.g., styrene and hydroxystyrene), (meth)acrylate, norbornene, and combinations thereof. In a preferred aspect, the photoresist polymer is vinyl aromatic-based, wherein more than 50 mole % of the polymerized units in the polymer, typically more than 80 mole % of the polymerized units in the polymer, are formed from vinyl aromatic monomers.

The photoresist layer is disposed on the substrate over the antireflective layer 104 (if present). The photoresist composition can be applied to the substrate by spin-coating, dipping, roller-coating or other conventional coating technique. Of these, spin-coating is typical. For spin-coating, the solids content of the coating solution can be adjusted to provide a desired film thickness based upon the specific coating equipment utilized, the viscosity of the solution, the speed of the coating tool and the amount of time allowed for spinning A typical thickness for the photoresist layer 106 is from about 500 to 3000 Å.

The photoresist layer 106 is typically next softbaked to minimize the solvent content in the layer, thereby forming a tack-free coating and improving adhesion of the layer to the substrate. The softbake can be conducted on a hotplate or in an oven, with a hotplate being typical. The softbake temperature and time will depend, for example, on the particular material of the photoresist and thickness. Typical softbakes are conducted at a temperature of from about 90 to 150° C., and a time of from about 30 to 90 seconds.

The photoresist layer 106 is next exposed to activating radiation 108 through a photomask 110 to create a difference in solubility between exposed and unexposed regions. References herein to exposing a photoresist composition to radiation that is activating for the composition indicates that the radiation is capable of forming a latent image in the photoresist composition. The photomask has optically transparent and optically opaque regions corresponding to regions of the resist layer to be exposed and unexposed, respectively, by the activating radiation. The exposure wavelength is typically sub-400 nm, sub-300 nm, such as deep-UV (248 nm), 193 nm or an EUV wavelength (e.g., 13.5 nm). In a preferred aspect, the exposure wavelength is deep-UV or EUV lithography. The exposure energy is typically from about 10 to 80 mJ/cm², depending, for example, on the exposure tool and the components of the photosensitive composition.

Following exposure of the photoresist layer 106, a post-exposure bake (PEB) is typically performed. The PEB can be conducted, for example, on a hotplate or in an oven. Conditions for the PEB will depend, for example, on the particular photoresist composition and layer thickness. The PEB is typically conducted at a temperature of from about 80 to 150° C., and a time of from about 30 to 90 seconds. A latent image defined by the boundary between polarity-switched and unswitched regions (corresponding to exposed and unexposed regions, respectively) is thereby formed.

The photoresist layer 106 is next developed to remove exposed regions of the layer, leaving unexposed regions forming a resist pattern 106′ having a plurality of features as shown in FIG. 1B. The features are not limited and can include, for example, a plurality of lines, pillars and/or contact hole patterns which allow for the formation of such patterns in the underlying layers to be patterned. The formed resist patterns have an initial dimension shown as L₁, a linewidth for line patterns, post diameter for post patterns, or sidewall width for contact hole patterns.

A layer 112 of a photoresist pattern trimming composition as described herein is formed over the photoresist pattern 106′ as shown in FIG. 1C. The trimming composition is typically applied to the substrate by spin-coating. The solids content of the coating solution can be adjusted to provide a desired film thickness based upon the specific coating equipment utilized, the viscosity of the solution, the speed of the coating tool and the amount of time allowed for spinning A typical thickness for the pattern trimming composition layer 112 is from 200 to 1500 Å, typically measured on an unpatterned substrate.

As shown in FIG. 1D, the substrate is next baked to remove solvent in the trimming composition layer. The bake also allows the acid of the trimming composition to diffuse into the surface of the resist pattern 106′ to cause a polarity-changing reaction in the resist pattern surface region 114. The bake can be conducted with a hotplate or oven, with a hotplate being typical. Suitable bake temperatures are greater than 50° C., for example, greater than 70° C., greater than 90° C., greater than 120° C. or greater than 150° C., with a temperature of from 70 to 160° C. and a time of from about 30 to 90 seconds being typical. While a single baking step is typical, multiple-step baking can be used and may be useful for resist profile adjustment.

The photoresist pattern is next contacted with a rinsing agent, typically a developing solution, to remove the residual trimming composition layer 112 and typically also the surface region 114 of the photoresist pattern, with the resulting pattern 106″ being shown in FIG. 1E. The rinsing agent is typically an aqueous alkaline developer, for example, a quaternary ammonium hydroxide solution, for example, a tetra-alkyl ammonium hydroxide solution such as 0.26 Normality (N) (2.38 wt %) tetramethylammonium hydroxide (TMAH). The rinsing agent can further be or comprise water. The resulting structure is shown in FIG. 1E. The resist pattern after trimming treatment has a dimension (L₂) that is smaller as compared with the feature size prior to trimming treatment.

Using the resist pattern 106″ as an etch mask, the BARC layer 104 is selectively etched to form BARC patterns 104′, exposing the underlying hardmask layer 103, as shown in FIG. 1F. The hardmask layer is next selectively etched, again using the resist pattern as an etch mask, resulting in patterned BARC and hardmask layer 103′, as shown in FIG. 1G. Suitable etching techniques and chemistries for etching the BARC layer and hardmask layer are known in the art and will depend, for example, on the particular materials of these layers. Dry-etching processes such as reactive ion etching are typical. The resist pattern 106″ and patterned BARC layer 104′ are next removed from the substrate using known techniques, for example, oxygen plasma ashing. Using the hardmask pattern 103′ as an etch mask, the one or more layers 102 are then selectively etched. Suitable etching techniques and chemistries for etching the underlying layers 102 are known in the art, with dry-etching processes such as reactive ion etching being typical. The patterned hardmask layer 103′ can next be removed from the substrate surface using known techniques, for example, a dry-etching process such as reactive ion etching or a wet strip. The resulting structure is a pattern of etched features 102′ as illustrated in FIG. 1H. In an alternative exemplary method, it may be desirable to pattern the layer 102 directly using the photoresist pattern 106″ without the use of a hardmask layer 103. Whether direct patterning with the resist patterns can be employed will depend on factors such as the materials involved, resist selectivity, resist pattern thickness and pattern dimensions.

The following non-limiting examples are illustrative of the invention.

### Examples

### Polymer Synthesis

The following monomers were used to synthesize polymers according to the procedures described below:

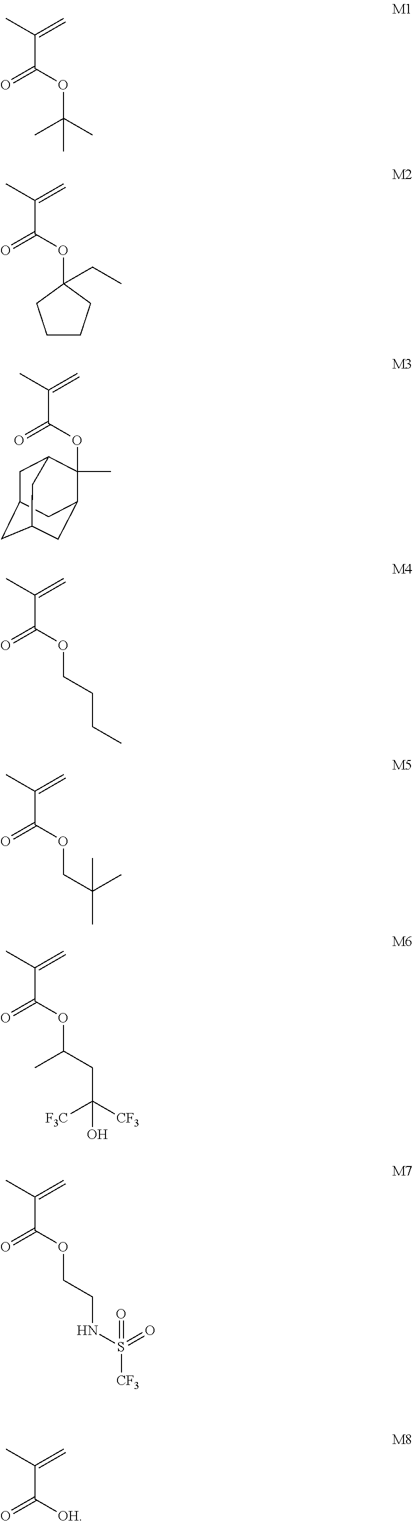

### Example 1 (Polymer P1)

A feed solution was prepared by combining 18.56 g propylene glycol monomethyl ether acetate (PGMEA), 20.0 g monomer M1, 20.0 g monomer M4, and 1.44 g V-601 free radical initiator (Wako Chemical Company) in a container and agitating the mixture to dissolve the components. 20 g PGMEA was introduced into a reaction vessel and the vessel was purged with nitrogen for 30 minutes. The reaction vessel was next heated to 95° C. with agitation. The feed solution was then introduced into the reaction vessel and fed over a period of 2 hours. The reaction vessel was maintained at 95° C. for an additional three hours with agitation and was then allowed to cool to room temperature. The polymer (P1) was precipitated by dropwise addition of the reaction mixture into methanol/water 20/80 (wt %), collected by filtration, and dried in vacuo to yield 32 g of solids (80% yield). Weight average molecular weight (Mw) and number average molecular weight (Mn) were determined for this and subsequent examples by polystyrene equivalent value as measured by gel permeation chromatography (GPC), and polydispersity was calculated as PDI=Mw/Mn. The monomer ratios in the polymer and molecular weight results for this and subsequent polymer synthesis examples are shown in Table 1.

### Example 2 (Polymer P2)

A feed solution was prepared by combining 18.56 g propylene glycol monomethyl ether acetate (PGMEA), 20.0 g monomer M2, 20.0 g monomer M4, and 1.44 g V-601 free radical initiator (Wako Chemical Company) in a container and agitating the mixture to dissolve the components. 20 g PGMEA was introduced into a reaction vessel and the vessel was purged with nitrogen for 30 minutes. The reaction vessel was next heated to 95° C. with agitation. The feed solution was then introduced into the reaction vessel and fed over a period of 2 hours. The reaction vessel was maintained at 95° C. for an additional three hours with agitation and was then allowed to cool to room temperature. The polymer (P2) was precipitated by dropwise addition of the reaction mixture into methanol/water 25/75 (wt %), collected by filtration, and dried in vacuo to yield 31.5 g of solids (78.75% yield).

### Example 3 (Polymer P3)

A feed solution was prepared by combining 17.32 g propylene glycol monomethyl ether acetate (PGMEA), 15.0 g monomer M3, 15.0 g monomer M4, and 1.42 g V-601 free radical initiator (Wako Chemical Company) in a container and agitating the mixture to dissolve the components. 22 g PGMEA was introduced into a reaction vessel and the vessel was purged with nitrogen for 30 minutes. The reaction vessel was next heated to 95° C. with agitation. The feed solution was then introduced into the reaction vessel and fed over a period of 2 hours. The reaction vessel was maintained at 95° C. for an additional three hours with agitation and was then allowed to cool to room temperature. The polymer (P3) was precipitated by dropwise addition of the reaction mixture into methanol/water 25/75 (wt %), collected by filtration, and dried in vacuo to yield 22 g of solids (73.3% yield).

### Example 4 (Polymer P4)

A feed solution was prepared by combining 23.20 g propylene glycol monomethyl ether acetate (PGMEA), 25.0 g monomer M2, 25.0 g monomer M5, and 1.80 g V-601 free radical initiator (Wako Chemical Company) in a container and agitating the mixture to dissolve the components. 25 g PGMEA was introduced into a reaction vessel and the vessel was purged with nitrogen for 30 minutes. The reaction vessel was next heated to 95° C. with agitation. The feed solution was then introduced into the reaction vessel and fed over a period of 2 hours. The reaction vessel was maintained at 95° C. for an additional three hours with agitation and was then allowed to cool to room temperature. The polymer (P4) was precipitated by dropwise addition of the reaction mixture into methanol/water 25/75 (wt %), collected by filtration, and dried in vacuo to yield 42 g of solids (84% yield).

### Example 5 (Polymer P5)

A feed solution was prepared by combining 18.56 g propylene glycol monomethyl ether acetate (PGMEA), 28.0 g monomer M1, 12.0 g monomer M6, and 1.44 g V-601 free radical initiator (Wako Chemical Company) in a container and agitating the mixture to dissolve the components. 20 g PGMEA was introduced into a reaction vessel and the vessel was purged with nitrogen for 30 minutes. The reaction vessel was next heated to 95° C. with agitation. The feed solution was then introduced into the reaction vessel and fed over a period of 2 hours. The reaction vessel was maintained at 95° C. for an additional three hours with agitation and was then allowed to cool to room temperature. The polymer (P5) was precipitated by dropwise addition of the reaction mixture into methanol/water 35/65 (wt %), collected by filtration, and dried in vacuo to yield 30.7 g of solids (76.75% yield).

### Example 6 (Polymer P6)

A feed solution was prepared by combining 18.56 g propylene glycol monomethyl ether acetate (PGMEA), 12.0 g monomer M1, 28.0 g monomer M6, and 1.44 g V-601 free radical initiator (Wako Chemical Company) in a container and agitating the mixture to dissolve the components. 20 g PGMEA was introduced into a reaction vessel and the vessel was purged with nitrogen for 30 minutes. The reaction vessel was next heated to 95° C. with agitation. The feed solution was then introduced into the reaction vessel and fed over a period of 2 hours. The reaction vessel was maintained at 95° C. for an additional three hours with agitation and was then allowed to cool to room temperature. The polymer (P6) was precipitated by dropwise addition of the reaction mixture into methanol/water 15/85 (wt %), collected by filtration, and dried in vacuo to yield 32 g of solids (80% yield).

### Example 7 (Polymer P7)

A feed solution was prepared by combining 18.56 g propylene glycol monomethyl ether acetate (PGMEA), 16.0 g monomer M2, 20.0 g monomer M4, 4.0 g monomer M6, and 1.44 g V-601 free radical initiator (Wako Chemical Company) in a container and agitating the mixture to dissolve the components. 20 g PGMEA was introduced into a reaction vessel and the vessel was purged with nitrogen for 30 minutes. The reaction vessel was next heated to 95° C. with agitation. The feed solution was then introduced into the reaction vessel and fed over a period of 2 hours. The reaction vessel was maintained at 95° C. for an additional three hours with agitation and was then allowed to cool to room temperature. The polymer (P7) was precipitated by dropwise addition of the reaction mixture into methanol/water 25/75 (wt %), collected by filtration, and dried in vacuo to yield 33 g of solids (82.5% yield).

### Example 8 (Polymer P8)

A feed solution was prepared by combining 18.56 g propylene glycol monomethyl ether acetate (PGMEA), 16.0 g monomer M1, 20.0 g monomer M4, 4.0 g monomer M6, and 1.44 g V-601 free radical initiator (Wako Chemical Company) in a container and agitating the mixture to dissolve the components. 20 g PGMEA was introduced into a reaction vessel and the vessel was purged with nitrogen for 30 minutes. The reaction vessel was next heated to 95° C. with agitation. The feed solution was then introduced into the reaction vessel and fed over a period of 2 hours. The reaction vessel was maintained at 95° C. for an additional three hours with agitation and was then allowed to cool to room temperature. The polymer (P8) was precipitated by dropwise addition of the reaction mixture into methanol/water 25/75 (wt %), collected by filtration, and dried in vacuo to yield 30.5 g of solids (76% yield).

### Example 9 (Polymer P9)

A feed solution was prepared by combining 23.20 g propylene glycol monomethyl ether acetate (PGMEA), 20.0 g monomer M2, 25.0 g monomer M4, 5.0 g monomer M7, and 1.80 g V-601 free radical initiator (Wako Chemical Company) in a container and agitating the mixture to dissolve the components. 25 g PGMEA was introduced into a reaction vessel and the vessel was purged with nitrogen for 30 minutes. The reaction vessel was next heated to 95° C. with agitation. The feed solution was then introduced into the reaction vessel and fed over a period of 2 hours. The reaction vessel was maintained at 95° C. for an additional three hours with agitation and was then allowed to cool to room temperature. The polymer (P9) was precipitated by dropwise addition of the reaction mixture into methanol/water 40/60 (wt %), collected by filtration, and dried in vacuo to yield 42 g of solids (82% yield).

### Example 10 (Polymer CP1)

A monomer feed solution was prepared by mixing 7.56 g 4-methyl-2-pentanol (MIBC) and 40.50 g monomer M4 in a container. An initiator feed solution was prepared by combining 3.52 g V-601 free radical initiator (Wako Chemical Company) and 23.57 g of MIBC in a container and agitating the mixture to dissolve the initiator. 14.85 g of MIBC was introduced into a reaction vessel and the vessel was purged with nitrogen for 30 minutes. The reaction vessel was next heated to 88° C. with agitation. Introduction of the monomer feed solution and initiator feed solution into the reaction vessel was simultaneously started. The monomer feed solution was fed over a period of 1.5 hours and the initiator feed solution was fed over a period of 2 hours. The reaction vessel was maintained at 88° C. for an additional 3 hours with agitation, and was then allowed to cool to room temperature. The polymer (CP1) was precipitated by dropwise addition of the reaction mixture into heptane, collected by filtration, and dried in vacuo to yield 30 g of solids (74% yield).

### Example 11 (Polymer CP2)

A monomer feed solution was prepared by mixing 6.13 g 4-methyl-2-pentanol (MIBC), 20.25 g monomer M4, and 20.25 g monomer M8 in a container. An initiator feed solution was prepared by combining 7.13 g V-601 free radical initiator (Wako Chemical Company) and 21.39 g of MIBC in a container and agitating the mixture to dissolve the initiator. 14.85 g of MIBC was introduced into a reaction vessel and the vessel was purged with nitrogen gas for 30 minutes. The reaction vessel was next heated to 88° C. with agitation. Introduction of the monomer feed solution and initiator feed solution into the reaction vessel was simultaneously started. The monomer feed solution was fed over a period of 1.5 hours and the initiator feed solution was fed over a period of 2 hours. The reaction vessel was maintained at 88° C. for an additional 3 hours with agitation and was then allowed to cool to room temperature. The polymer (CP2) was precipitated by dropwise addition of the reaction mixture into heptane, collected by filtration, and dried in vacuo to yield 30 g of solids (74% yield).

### Example 12 (Polymer CP3)

A monomer feed solution was prepared by mixing 2.83 g propylene glycol monomethyl ether (PGME), 27.20 g monomer M6, and 4.80 g monomer M8 in a container. An initiator feed solution was prepared by combining 1.48 g Vazo-67 free radical initiator (E. I. du Pont de Nemours and Company) and 19.69 g of PGME in a container and agitating the mixture to dissolve the initiator. 24.00 g of PGME was introduced into a reaction vessel and the vessel was purged with nitrogen gas for 30 minutes. The reaction vessel was next heated to 90° C. with agitation. Introduction of the monomer feed solution and initiator feed solution into the reaction vessel was simultaneously started. The monomer feed solution was fed over a period of 2 hours and the initiator feed solution was fed over a period of 3 hours. The reaction vessel was maintained at 90° C. for an additional 7 hours with agitation and was then allowed to cool to room temperature. The polymer (CP3) was precipitated by dropwise addition of the reaction mixture into heptane, collected by filtration, and dried in vacuo to yield 25 g of solids (78% yield).

TABLE 1

| | | Monomer A | Monomer B | Monomer C | | | |
|---|---|---|---|---|---|---|---|
| Example | Polymer | (wt %) | (wt %) | (wt %) | Mw (Da) | Mn (Da) | PDI |
| Ex. 1 | P1 | M1 (50) | M4 (50) | — | 12750 | 5744 | 2.22 |
| Ex. 2 | P2 | M2 (50) | M4 (50) | — | 10180 | 5698 | 1.78 |
| Ex. 3 | P3 | M3 (50) | M4 (50) | — | 9261 | 6044 | 1.53 |
| Ex. 4 | P4 | M2(50) | M5(50) | — | 11110 | 6306 | 1.76 |
| Ex. 5 | P5 | M1 (70) | M6 (30) | — | 8146 | 4784 | 1.70 |
| Ex. 6 | P6 | M1 (30) | M6 (70) | — | 9223 | 5590 | 1.65 |
| Ex. 7 | P7 | M2 (40) | M4 (50) | M6 (10) | 10698 | 5703 | 1.88 |
| Ex. 8 | P8 | M1 (40) | M4 (50) | M6 (10) | 12669 | 7226 | 1.75 |
| Ex. 9 | P9 | M2 (40) | M4 (50) | M7 (10) | 10784 | 5233 | 2.06 |
| Ex. 10 (Comp) | CP1 | M4 (100) | — | — | 13452 | 7844 | 1.72 |
| Ex. 11 (Comp) | CP2 | M4 (50) | M8 (50) | — | 7840 | 4492 | 1.75 |
| Ex. 12 (Comp) | CP3 | M6 (85) | M8 (15) | — | 14223 | 6189 | 2.3 |

### Thermal Acid Generator (TAG) Synthesis

### Example 13 (TAG1)

2,3-Difluoropyridine (7.25 g, 0.063 mol) was added to a solution of 4-dodecylbenzene sulfonic acid (16.00 g, 0.049 mol) in methanol (250 mL). The resulting mixture was stirred overnight at room temperature. The resulting reaction mixture was concentrated under reduced pressure to yield a solid crude product, which was then washed with heptane (300 mL). The solids were filtered and washed with methyl tertiary butyl ether (100 mL) to yield acid generator TAG1 at a 00% yield.

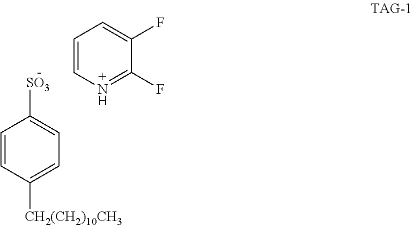

### Example 14 (TAG2)

3-Fluoropyridine (6.12 g, 0.063 mol) was added to a solution of 4-dodecylbenzene sulfonic acid (16.00 g, 0.049 mol) in methanol (250 mL). The resulting mixture was stirred overnight at room temperature. The resulting reaction mixture was concentrated under reduced pressure to yield a solid crude product, which was then washed with heptane (300 mL). The solids were filtered and washed with methyl tertiary butyl ether (100 mL) to yield acid generator TAG-2 at a 92% yield.

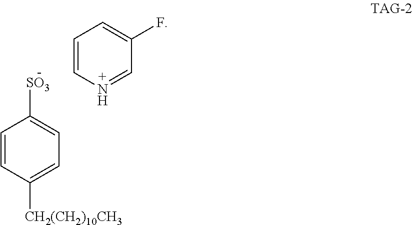

### Preparation of Pattern Trimming Compositions

Photoresist pattern trimming compositions (PTCs) were prepared by dissolving solid components in solvents using the materials and amounts set forth in Table 2. The resulting mixtures, made on a 14-30 g scale, were shaken on a mechanical shaker for from 3 to 24 hours and then filtered through a PTFE disk-shaped filter having a 0.2 micron pore size.

TABLE 2

| | Pattern | | | | | |
|---|---|---|---|---|---|---|
| | Trimming | Polymer | Acid or TAG | Solvent B1 | Solvent B2 | Solvent B3 |
| Example | Composition | (wt %) | (wt %) | (wt %) | (wt %) | (wt %) |
| Ex. 15 | PTC-1 | P1 (1.76) | TAG1 (0.24) | 88.20 | 9.80 | — |
| Ex. 16 | PTC-2 | P2 (2.898) | TAG2 (0.102) | 86.33 | 9.70 | 0.97 |
| Ex. 17 | PTC-3 | P3 (2.88) | A1 (0.12) | 87.30 | 9.70 | — |
| Ex. 18 | PTC-4 | P4 (2.78) | TAG2 (0.10) | 87.41 | 9.71 | — |
| Ex. 19 | PTC-5 | P5 (2.91) | TAG2 (0.09) | 87.30 | 9.70 | — |
| Ex. 20 | PTC-6 | P6 (2.91) | A1 (0.14) | 94.04 | 2.91 | — |
| Ex. 21 | PTC-7 | P7 (2.91) | TAG2 (0.09) | 92.15 | 4.85 | — |
| Ex. 22 | PTC-8 | P8 (3.01) | A1 (0.08) | 92.06 | 4.85 | — |
| Ex. 23 | PTC-9 | P9 (2.90) | TAG2 (0.09) | 87.31 | 9.70 | — |
| Ex. 24 (Comp) | PTC-10 | CP1 (2.88) | A1 (0.12) | 87.30 | 9.70 | — |
| Ex. 25 (Comp) | PTC-11 | CP2 (3.00) | — | 87.30 | 9.70 | — |
| Ex. 26 (Comp) | PTC-12 | CP3 (2.91) | A1 (0.09) | 87.30 | 9.70 | — |

B1 = diisoamyl ether;
B2 = 4-methyl-2-pentanol;
B3 = tripropylene glycol monomethyl ether;
A1 = 4-dodecylbenzenesulfonic acid (King Industries, Inc.);
All amounts provided as weight percent (wt %) based on total pattern trimming composition.

### Solubility Evaluation

### Examples 27-38 (Polymer Solubility in Organic Solvent)

The polymers of Examples 1-12 were separately combined with isoamyl ether/4-methyl-2-pentanol (97/3 weight ratio) in an amount of 10 wt % polymer based on total solution. The solutions were shaken for 2 hours and polymer solubility was checked both visually and using a turbidity meter (Orbeco-Hellige). The polymers were deemed soluble in the ether-based solvent if the solution was visually clear and exhibited a turbidity of <1 NTU. The results are shown in Table 3, with “Yes” or “No” indicating the polymer was soluble or insoluble, respectively, in the solvent.

### Examples 39-50 (Film Solubility in Rinsing Agent)

The pattern trimming compositions of Examples 15-26 were each coated on a respective 8-inch silicon wafer on a TEL Clean Track Act 8 coating tool with a spin-speed of 1500 rpm. The coated wafers were baked for 60 seconds at a temperature of 100° C. to a dried film thickness of 40 nm as measured by a Therma-Wave Opti-Probe 5230 metrology tool. The wafers were then rinsed with a 0.26N TMAH solution. After treatment with the rinsing agent, film thickness was measured again. The change in film thickness (ΔFT) before and after TMAH rinse was calculated using the following equation:

ΔFT=FTᵢ−FT_{f}

wherein FTᵢ is the film thickness prior to TMAH rinse, and FT_{f} is the film thickness after rinse. The results are shown in Table 3, with “Yes” or “No” indicating the film was soluble or insoluble, respectively, in the TMAH rinsing agent.

TABLE 3

| | | IAE/MIBC (97/3) | | Pattern Trimming | TMAH |
|---|---|---|---|---|---|
| Example | Polymer | Solubility | Example | Composition | Solubility |
| Ex. 27 | P1 | Yes | Ex. 39 | PTC-1 | Yes |
| Ex. 28 | P2 | Yes | Ex. 40 | PTC-2 | Yes |
| Ex. 29 | P3 | Yes | Ex. 41 | PTC-3 | Yes |
| Ex. 30 | P4 | Yes | Ex. 42 | PTC-4 | Yes |
| Ex. 31 | P5 | Yes | Ex. 43 | PTC-5 | Yes |
| Ex. 32 | P6 | Yes | Ex. 44 | PTC-6 | Yes |
| Ex. 33 | P7 | Yes | Ex. 45 | PTC-7 | Yes |
| Ex. 34 | P8 | Yes | Ex. 46 | PTC-8 | Yes |
| Ex. 35 | P9 | Yes | Ex. 47 | PTC-9 | Yes |
| Ex. 36 (Comp) | CP1 | Yes | Ex. 48 (Comp) | PTC-10 | No |
| Ex. 37 (Comp) | CP2 | No | Ex. 49 (Comp) | PTC-11 | N/A |
| Ex. 38 (Comp) | CP3 | No | Ex. 50 (Comp) | PTC-12 | N/A |

### Photoresist Pattern Trimming Composition Evaluation

### Pattern Trim Evaluation

8-inch silicon wafers coated with a 600 nm BARC layer (ARTM3 antireflectant, DuPont Electronics & Imaging) were spin-coated on a TEL Clean Track Act 8 coating tool with UV217 photoresist (DuPont Electronics & Imaging) and softbaked at 130° C. for 60 seconds to provide a resist layer thickness of 3550 Å. The wafers were exposed using a Canon ES4 FPA 5000 scanner with NA=0.68, Conventional illumination (0.75 sigma), using a mask having line and space patterns with binary feature size of 140 nm 1:1. The exposed wafers were post-exposure baked at 125° C. for 60 seconds and developed with a 0.26N TMAH solution to form photoresist patterns having 140 nm 1:1 line-space patterns (duty ratio=1:1). CD linewidth measurements of the formed patterns were made using a Hitachi High Technologies Co. CG4000 CD-SEM to obtain initial CD values.

The wafers were next coated with 400 Å of a respective pattern trimming composition with a spin-speed of 1500 rpm, baked for 60 seconds at a temperature described in Table 4, rinsed with 0.26 N aqueous TMAH solution for 30 seconds, rinsed with distilled water and spun dry on a TEL Clean Track Act 8 coating tool. CD measurements of the resist patterns for the treated wafers were then made to obtain final CD values. The change in CD (ΔCD) for the treated patterns for each wafer was calculated according to the following equation:

ΔCD=CDᵢ−CD_{f}

wherein CD_{f} is the average CD measurement after pattern trimming treatment, and CDᵢ is the average CD measurement prior to pattern trimming treatment. The results are shown in Table 4. The wafers were also inspected with an optical microscope to determine if any residue remained in the spaces between lines of the resist patterns.

TABLE 4

| | Pattern | | | |
|---|---|---|---|---|
| | Trimming | Bake Temp. | | |
| Example | Composition | (° C.) | ΔCD (nm) | Residue |
| Ex. 39 | PTC-1 | 110 | 35.0 | None |
| Ex. 40 | PTC-2 | 110 | 27.4 | None |
| Ex. 41 | PTC-3 | 100 | 35.5 | None |
| Ex. 42 | PTC-4 | 100 | 28.9 | None |
| Ex. 43 | PTC-5 | 110 | 33.7 | None |
| Ex. 44 | PTC-6 | 100 | 36.2 | None |
| Ex. 45 | PTC-7 | 100 | 23.5 | None |
| Ex. 46 | PTC-8 | 110 | 34.3 | None |
| Ex. 47 | PTC-9 | 110 | 36.4 | None |
| Ex. 48 (Comp) | PTC-10 | 80 | −62.0 | Yes |
| Ex. 49 (Comp) | PTC-11 | N/A | N/A | N/A |
| Ex. 50 (Comp) | PTC-12 | 100 | * | Yes |

* CD could not be measured due to extent of residue.

1. A photoresist pattern trimming composition, comprising:
a polymer comprising as polymerized units a monomer comprising an acid-decomposable group, the decomposition of which group forms a carboxylic acid group on the polymer;
a non-polymeric acid or a non-polymeric thermal acid generator; and
an organic-based solvent system comprising one or more organic solvents.

2. The photoresist pattern trimming composition of claim 1, wherein the acid-decomposable group is a tertiary alkyl ester.

3. The photoresist pattern trimming composition of claim 1, wherein the acid-decomposable group is an acetal group.

4. The photoresist pattern trimming composition of claim 1, wherein the polymer further comprises as polymerized units a monomer comprising (i) a fluoroalcohol group, or (ii) an acid-decomposable group, the decomposition of which group forms a fluoroalcohol group on the polymer.

5. The photoresist pattern trimming composition of any of claim 1, wherein the polymer further comprises as polymerized units a monomer which is an unsubstituted C1-C10 alkyl (meth)acrylate monomer.

6. The photoresist pattern trimming composition of any of claim 1, wherein the combined content of all polymerized units of monomers comprising an acid-decomposable group, the decomposition of which group forms a carboxylic acid group on the polymer, is from 30 to 100 mole % based on total polymerized units of the polymer.

7. The photoresist pattern trimming composition of any of claim 1, wherein the polymer is free of acid groups.

8. The photoresist pattern trimming composition of any of claim 1, wherein the organic-based solvent system comprises a monoether.

9. The photoresist pattern trimming composition of claim 8, wherein the organic-based solvent system further comprises an alcohol and/or an ester.

10. A method of trimming a photoresist pattern, comprising:
(a) providing a semiconductor substrate;
(b) forming a photoresist pattern over the semiconductor substrate, wherein the photoresist pattern is formed from a photoresist composition comprising a photoacid generator and a polymer comprising acid-decomposable groups;
(c) coating a pattern trimming composition of any claim 1 over the photoresist pattern;
(d) heating the coated photoresist pattern; and
(e) rinsing the coated and heated photoresist pattern with a rinsing agent to remove a surface region of the photoresist pattern.

11. The method of claim 10, wherein the rinsing agent is an aqueous tetramethylammonium hydroxide solution.

12. The method of claim 10, wherein the photoresist pattern is formed by KrF or EUV lithography.

13. The method of claim 10, wherein the acid-decomposable group is a tertiary alkyl ester.

14. The method of claim 10, wherein the acid-decomposable group is an acetal group.

15. The method of claim 10, wherein the polymer further comprises as polymerized units a monomer comprising (i) a fluoroalcohol group, or (ii) an acid-decomposable group, the decomposition of which group forms a fluoroalcohol group on the polymer.

16. The method of claim 10, wherein the polymer further comprises as polymerized units a monomer which is an unsubstituted C1-C10 alkyl (meth)acrylate monomer.

17. The method of claim 10, wherein the combined content of all polymerized units of monomers comprising an acid-decomposable group, the decomposition of which group forms a carboxylic acid group on the polymer, is from 30 to 100 mole % based on total polymerized units of the polymer.

18. The method of claim 10, wherein the polymer is free of acid groups.

19. The method of claim 10, wherein the organic-based solvent system comprises a monoether.

20. The method of claim 10, wherein the organic-based solvent system further comprises an alcohol and/or an ester.
